(19) United States
(12) Patent Application Publication
(10) Pub. No.: US 2025/0294873 A1
(43) Pub. Date: Sep. 18, 2025

(54) THREE-DIMENSIONAL SEMICONDUCTOR DEVICE AND METHOD OF MANUFACTURING THE SAME

(71) Applicant: Samsung Electronics Co., Ltd., Suwon-si (KR)

(72) Inventors: Donghoon Hwang, Suwon-si (KR); Jaeho Jeon, Suwon-si (KR); Seongkwang Kim, Suwon-si (KR); Wonchang Lee, Suwon-si (KR)

(21) Appl. No.: 18/944,585

(22) Filed: Nov. 12, 2024

(30) Foreign Application Priority Data
Mar. 13, 2024 (KR) 10-2024-0035375

(51) Int. Cl. H01L 27/092; H01L 21/822; H01L 21/8238; H01L 29/06; H01L 29/417; H01L 29/423; H01L 29/66; H01L 29/775; H01L 29/786

(52) U.S. Cl. CPC H10D 84/856; H10D 30/014; H10D 30/43; H10D 30/6729; H10D 30/6735; H10D 30/6757; H10D 62/121; H10D 64/017; H10D 84/0167; H10D 84/017; H10D 84/0186; H10D 84/038; H10D 88/01

(57) ABSTRACT

A three-dimensional semiconductor device includes a first active region on a substrate, the first active region including a lower channel pattern and a lower source/drain pattern electrically connected to the lower channel pattern, a second active region on the first active region, the second active region including an upper channel pattern and an upper source/drain pattern electrically connected to the upper channel pattern, a gate electrode on the lower channel pattern and the upper channel pattern, the gate electrode extending in a first direction, an insulating structure on the first active region and the second active region, the insulating structure extending in a second direction intersecting the first direction. The insulating structure includes a first portion having a first width and a second portion on the first portion, the second portion having a second width, and the first width is greater than the second width.

### CROSS-REFERENCE TO RELATED APPLICATIONS

This U.S. non-provisional patent application claims priority under 35 U.S.C. § 119 to Korean Patent Application No. 10-2024-0035375, filed on Mar. 13, 2024, in the Korean Intellectual Property Office, the entire contents of which are hereby incorporated by reference.

### BACKGROUND

The inventive concept relates to a three-dimensional semiconductor device and a method of manufacturing the same, and more particularly, relates to a three-dimensional semiconductor device including a field effect transistor and a method of manufacturing the same.

A semiconductor device includes an integrated circuit including metal-oxide-semiconductor field effect transistors (MOSFET). To meet an increasing demand for a semiconductor device with a small pattern size and a reduced design rule, the MOS-FETs are being aggressively scaled down. The scale-down of the MOS-FETs may lead to deterioration in operational properties of the semiconductor device. A variety of studies are being conducted to overcome technical limitations associated with the scale-down of the semiconductor device and to realize high-performance semiconductor devices.

### SUMMARY

Embodiments of the inventive concept provide a three-dimensional semiconductor device with improved integration and electrical characteristics.

The problem to be solved by the inventive concept is not limited to the problems mentioned above, and other problems not mentioned will be clearly understood by those skilled in the art from the description below.

According to embodiments of the inventive concept, a three-dimensional semiconductor device may include a first active region on a substrate, the first active region including a lower channel pattern and a lower source/drain pattern electrically connected to the lower channel pattern, a second active region on the first active region, the second active region including an upper channel pattern and an upper source/drain pattern electrically connected to the upper channel pattern, a gate electrode on the lower channel pattern and the upper channel pattern, the gate electrode extending in a first direction, an insulating structure on the first active region and the second active region, the insulating structure extending in a second direction intersecting the first direction, wherein the insulating structure includes a first portion having a first width and a second portion on the first portion, the second portion having a second width, and the first width is greater than the second width.

According to embodiments of the inventive concept, a three-dimensional semiconductor device may include a first active region on a substrate, the first active region including a lower channel pattern and a lower source/drain pattern electrically connected to the lower channel pattern, a second active region on the first active region, the second active region including an upper channel pattern and an upper source/drain pattern electrically connected to the upper channel, a gate electrode on the lower channel pattern and the upper channel pattern, the gate electrode extending in a first direction, and an insulating structure that extends into the first active region and the second active region, the insulating structure extending in a second direction intersecting the first direction, wherein the insulating structure includes a first portion in a first active region and a second portion on the first portion, and a first sidewall of the first portion is spaced apart from a second sidewall of the second portion in the first direction.

According to embodiments of the inventive concept, a three-dimensional semiconductor device may include a first active region on a substrate, the first active region including a lower channel pattern and lower source/drain patterns electrically connected to the lower channel pattern, a second active region on the first active region, the second active region including an upper channel pattern and an upper source/drain pattern electrically connected to the upper channel pattern, a gate electrode on the lower channel pattern and the upper channel pattern, the gate electrode extending in a first direction, a lower active contact electrically connected to the lower source/drain pattern, an upper active contact electrically connected to the upper source/drain pattern, a cutting pattern provided on one side of the substrate, the cutting pattern extending in a second direction, the second direction intersecting the first direction, a vertical via that extends into the cutting pattern, and an insulating structure spaced apart from the cutting pattern in the first direction on the substrate, wherein the insulating structure includes a first portion in the first active region and a second portion on the second active region, and a width of the first portion is greater than a width of the second portion, and the vertical via electrically connects the lower active contact and the upper active contact.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a conceptual view illustrating a logic cell of a semiconductor device according to a comparative example of the inventive concept.

FIG. 2 is a conceptual view illustrating a logic cell of a semiconductor device according to embodiments of the inventive concept.

FIG. 3 is a plan view illustrating a three-dimensional semiconductor device according to embodiments of the inventive concept.

FIGS. 4A, 4B, and 4C are cross-sectional views taken along lines A-A′, B-B′, and C-C′ of FIG. 3, respectively.

FIG. 5 is an enlarged view of region ‘M’ in FIG. 4B.

FIGS. 6A, 6B, and 6C are respectively enlarged views of region ‘M’ of FIG. 4B according to other embodiments of the inventive concept.

FIGS. 7A, 7B, 8, 9A, 9B, 10A, 10B, 11A, 11B, 12A, 12B, 13A, 13B, 14A, 14B, 15A, 15B, 15C, 16A, 16B, 16C, 17A, 17B, and 17C are cross-sectional views illustrating a method of manufacturing a semiconductor device according to embodiments of the inventive concept.

FIG. 18 is a cross-sectional view taken along line B-B′ of FIG. 3 according to embodiments of the inventive concept.

FIGS. 19A and 19B are respectively enlarged views of region ‘N’ of FIG. 18 according to embodiments of the inventive concept.

FIGS. 20A, 20B, and 20C are cross-sectional views illustrating a method of manufacturing a semiconductor device according to embodiments of the inventive concept.

FIGS. 21A and 21B are cross-sectional views illustrating a method of manufacturing a semiconductor device according to embodiments of the inventive concept.

### DETAILED DESCRIPTION

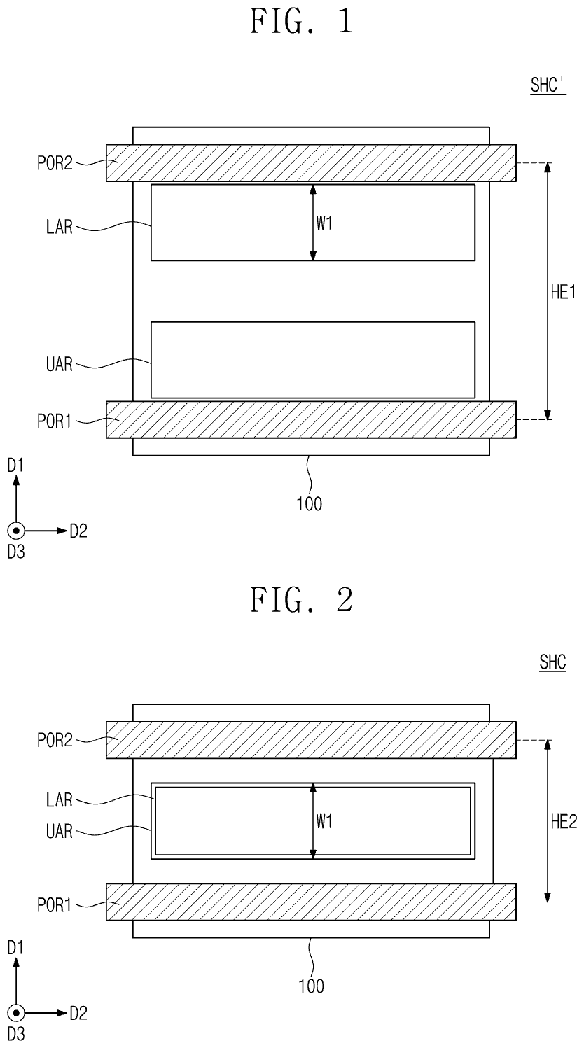

FIG. 1 is a conceptual view illustrating a logic cell of a semiconductor device according to a comparative example of the inventive concept. FIG. 1 shows a logic cell of a two-dimensional device according to a comparative example of the inventive concept.

Referring to FIG. 1, a single height cell SHC′ may be provided. For example, a substrate 100 may be provided thereon with a first power line POR1 and a second power line POR2. One of the first and second power lines POR1 and POR2 may be provided with a drain voltage (VDD) or a power voltage. The other of the first and second power lines POR1 and POR2 may be provided with a source voltage (VSS) or a ground voltage. For example, the source voltage (VSS) may be applied to the first power line POR1, and the drain voltage (VDD) may be applied to the second power line POR2.

The single height cell SHC′ may be defined between the first power line POR1 and the second power line POR2. The single height cell SHC′ may include a lower active region LAR and an upper active region UAR. One of the lower active region LAR and the upper active region UAR may be a p-channel metal oxide semiconductor field effect transistor (PMOSFET) region, and the other of the lower active region LAR and the upper active region UAR may be an n-channel metal oxide semiconductor field effect transistor (NMOSFET) region. For example, the lower active region LAR may be an NMOSFET region, and the upper active region UAR may be a PMOSFET region. That is, the single height cell SHC′ may have a complementary metal oxide semiconductor (CMOS) structure provided between the first power line POR1 and the second power line POR2.

The semiconductor device according to a comparative example may be a two-dimensional device in which transistors of a front-end-of-line (FEOL) layer are arranged two-dimensionally. For example, NMOSFETs on the lower active region LAR may be spaced apart in a first direction D1 from PMOSFETs on the upper active region UAR.

Each of the lower active region LAR and the upper active region UAR may have a first width W1 in the first direction D1. A first height HE1 may be defined to indicate a length in the first direction D1 of the single height cell SHC′ according to a comparative example. The first height HE1 may be substantially the same as a distance (e.g., pitch) between the first power line POR1 and the second power line POR2.

The single height cell SHC′ may constitute one logic cell. In this description, the logic cell may mean a logic device, such as, for example, AND, OR, XOR, XNOR, or inverter, that performs a specific function. For example, the logic cell may include transistors for constituting a logic device, and may also include wiring lines that connect the transistors to each other.

As a two-dimensional device is included in the single height cell SHC′ according to a comparative example, the lower active region LAR and the upper active region UAR may be spaced apart from each other in the first direction D1 without overlapping each other. Therefore, it may be required that the first height HE1 of the single height cell SHC′ be defined to include all of the lower active region LAR and the upper active region UAR that are spaced apart from each other in the first direction D1. As a result, the first height HE1 of the single height cell SHC′ according to a comparative example may be required to become relatively large. Therefore, the single height cell SHC′ according to a comparative example may have a relatively large area.

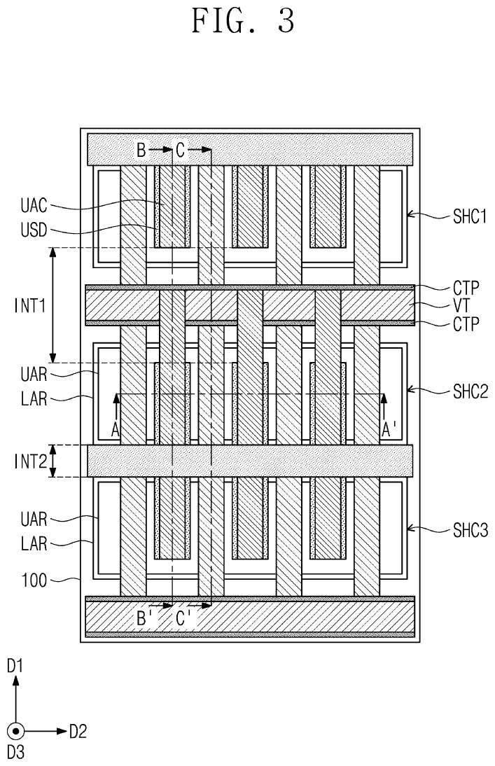

FIG. 2 is a conceptual view illustrating a logic cell of a semiconductor device according to embodiments of the inventive concept. FIG. 2 shows a logic cell of a three-dimensional device according to some embodiments of the inventive concept.

Referring to FIG. 2, a single height cell SHC may be provided to include a three-dimensional device such as a stacked transistor. In detail, a substrate 100 may be provided thereon with a first power line POR1 and a second power line POR2. The single height cell SHC may be defined between the first power line POR1 and the second power line POR2.

The single height cell SHC may include a lower active region LAR and an upper active region UAR. One of the lower active region LAR and the upper active region UAR may be a PMOSFET region, and the other of the lower active region LAR and the upper active region UAR may be an NMOSFET region.

A semiconductor device according to some embodiments of the present inventive concept may be a three-dimensional device in which transistors of a front-end-of-line (FEOL) layer are stacked vertically. The substrate 100 may be provided thereon with the lower active region LAR as a bottom tier, and the lower active region LAR may be provided thereon with the upper active region UAR as a top tier. For example, the substrate 100 may be provided thereon with NMOSFETs of the lower active region LAR, and the NMOSFETs may be provided thereon with PMOSFETs of the upper active region UAR. The lower active region LAR and the upper active region UAR may be spaced apart from each other in a vertical direction or a third direction D3.

The lower active region LAR and the upper active region UAR may each have a first width W1 in the first direction D1. A second height HE2 may be defined to indicate a length in the first direction D1 of the single height cell SHC according to some embodiments of the present inventive concept.

As the single height cell SHC according to some embodiments of the present inventive concept includes a three-dimensional device or a stacked transistor, the lower active region LAR and the upper active region UAR may overlap each other. Therefore, the second height HE2 of the single height cell SHC may have a size enough to cover or be greater than the first width W1. As a result, the second height HE2 of the single height cell SHC according to some embodiments of the present inventive concept may be smaller than the first height HE1 of the single height cell SHC′ discussed above in FIG. 1. That is, the single height cell SHC according to some embodiments of the present inventive concept may have a relatively small area. For a three-dimensional semiconductor device according to some embodiments of the present inventive concept, the area of a logic cell may be reduced to increase integration of the device.

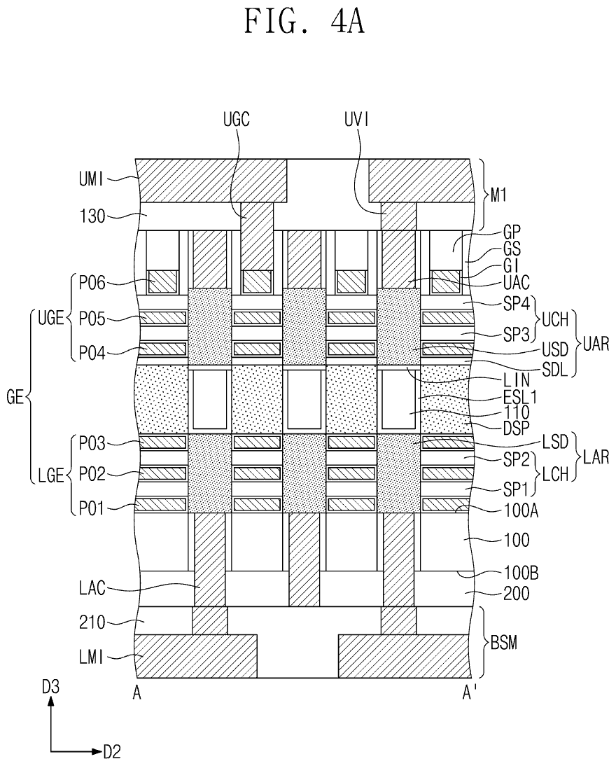

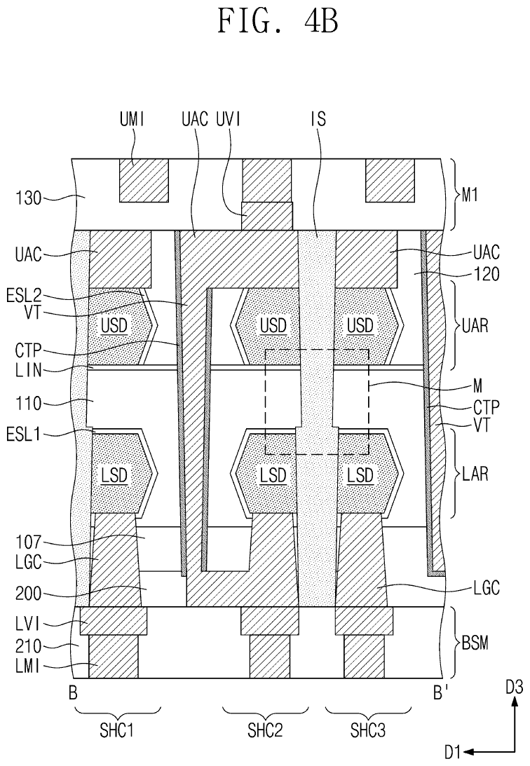

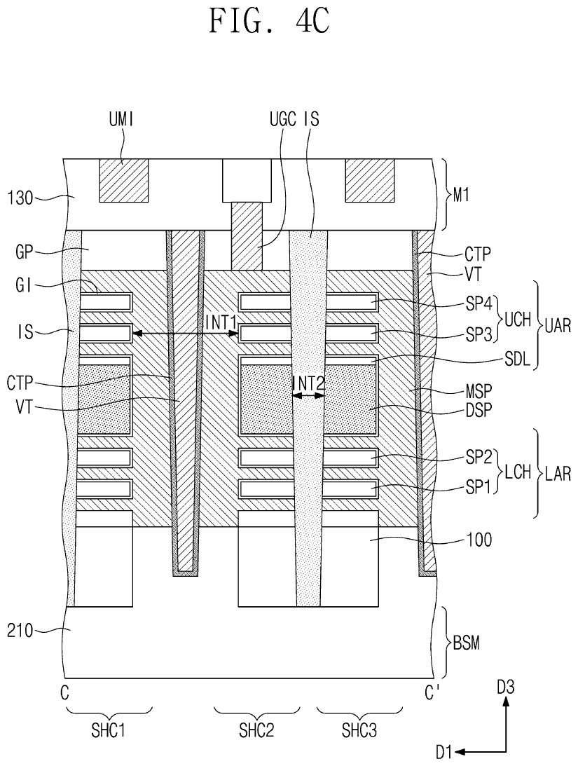

FIG. 3 is a plan view for explaining a three-dimensional semiconductor device according to embodiments of the inventive concept. FIGS. 4A, 4B, and 4C are cross-sectional views taken along lines A-A′, B-B′, and C-C′ of FIG. 3, respectively. The three-dimensional semiconductor device shown in FIGS. 3 and 4A, 4B, and 4C is an example that represents the single height cell of FIG. 2 in detail.

Referring to FIGS. 3 and 4A, 4B, and 4C, single height cells SHC may be provided on a substrate 100. The substrate 100 may include a first surface 100A and a second surface 100B facing each other. The first surface 100A may be a front side of the substrate 100, and the second surface 100B may be a back side of the substrate 100. In some embodiments of the inventive concept, the substrate 100 may be an insulating substrate including a silicon-based insulating material (e.g., silicon oxide and/or silicon nitride). In some embodiments of the inventive concept, the substrate 100 may be a semiconductor substrate containing silicon, germanium, silicon germanium, etc.

In some embodiments of the inventive concept, each single height cell SHC may be a logic cell constituting a logic circuit. Each single height cell SHC may be a logic cell including a three-dimensional element described above with reference to FIG. 2. The single height cells SHC may be arranged in a first direction D1.

A first single height cell SHC1, a second single height cell SHC2, and a third single height cell SHC3 may be provided to be spaced apart from each other in the first direction D1. The second single height cell SHC2 may be provided between the first single height cell SHC1 and the third single height cell SHC3.

The first single height cell SHC1 and the second single height cell SHC2 may be spaced apart from each other in the first direction D1 with a first interval INT1. The second single height cell SHC2 and the third single height cell SHC3 may be spaced apart from each other in the first direction D1 with a second interval INT2. The first interval INT1 may be greater than the second interval INT2. The second single height cell SHC may be provided closer to the third single height cell SHC3 than to the first single height cell SHC1.

Each single height cell SHC may include a lower active region LAR and an upper active region UAR sequentially stacked on the substrate 100. One of the lower and upper active regions LAR and UAR may be a PMOSFET region, and the other of the lower and upper active regions LAR and UAR may be an NMOSFET region. The lower active region LAR may be provided in a bottom tier of the FEOL layer, and the upper active region UAR may be provided in a top tier of the FEOL layer. The NMOSFET and PMOSFET of the lower and upper active regions LAR and UAR may be vertically stacked to form a three-dimensional stacked transistor. In one embodiment, the lower active region LAR may be an NMOSFET region, and the upper active region UAR may be a PMOSFET region.

Each of the lower and upper active regions LAR and UAR may have a bar shape or a line shape extending in a second direction D2. Either a cutting pattern CTP or an insulating structure IS may be provided between adjacent single height cells SHC. The cutting pattern CTP and the insulating structure IS may be alternately provided between the single height cells SHC. For example, the cutting pattern CTP may be provided on one side of the single height cells SHC, and an insulating structure IS may be provided on the other side thereof. As a result, the single height cell SHC may have an asymmetric structure.

The cutting pattern CTP may be provided between the first single height cell SHC1 and the second single height cell SHC2. The insulating structure IS may be provided between the second single height cell SHC2 and the third single height cell SHC3. When an interval between adjacent single height cells SHC is relatively large, the cutting pattern CTP may be provided. When the interval between adjacent single height cells SHC is relatively small, the insulating structure IS may be provided.

The cutting pattern CTP may separate adjacent single height cells SHC from each other. Adjacent single height cells SHC may be spaced apart in the first direction D1 by the cutting pattern CTP. The cutting pattern CTP may have a bar shape or a line shape extending in the second direction D2.

The insulating structure IS may separate adjacent single height cells SHC from each other. Adjacent single height cells SHC may be spaced apart in the first direction D1 by the insulating structure IS. The insulating structure IS may have a bar shape or a line shape extending in the second direction D2.

The lower active region LAR including lower channel patterns LCH and lower source/drain patterns LSD may be provided on the single height cell SHC. The lower channel pattern LCH may be interposed between a pair of lower source/drain patterns LSD. The lower channel pattern LCH may connect a pair of lower source/drain patterns LSD to each other.

The lower channel pattern LCH may include a first semiconductor pattern SP1 and a second semiconductor pattern SP2 that are stacked and spaced apart from each other. Each of the first and second semiconductor patterns SP1 and SP2 may include silicon (Si), germanium (Ge), or silicon germanium (SiGe). Each of the first and second semiconductor patterns SP1 and SP2 may include crystalline silicon. Each of the first and second semiconductor patterns SP1 and SP2 may be a nanosheet. For example, the lower channel pattern LCH may further include one or more semiconductor patterns that are stacked and spaced apart from the first semiconductor pattern SP1. The first semiconductor pattern SP1 may be the lowermost semiconductor pattern.

The lower source/drain patterns LSD may be provided on the substrate 100. Each lower source/drain pattern LSD may be an epitaxial pattern formed through a selective epitaxial growth (SEG) process. For example, an upper surface of the lower source/drain pattern LSD may be higher than an upper surface of the second semiconductor pattern SP2 of the lower channel pattern LCH.

The lower source/drain patterns LSD may be doped with impurities to have a first conductivity type. The first conductivity type may be N-type or P-type. In this example embodiment, the first conductivity type may be N-type. The lower source/drain patterns LSD may include silicon (Si) and/or silicon germanium (SiGe).

A first insulating layer ESL1 may be provided on the lower source/drain patterns LSD (refer to FIG. 4B). A first interlayer insulating layer 110 may be provided on the lower source/drain pattern LSD. The first interlayer insulating layer 110 may cover or overlap the lower source/drain patterns LSD. A first liner layer LIN may be formed to conformally cover the first interlayer insulating layer 110. The first liner layer LIN may be interposed between the first interlayer insulating layer 110 and the second interlayer insulating layer 120, which will be described later.

A lower active contact LAC may be provided below the lower source/drain pattern LSD. The lower active contact LAC may be electrically connected to the lower source/drain pattern LSD. The lower active contact LAC may be buried in the substrate 100. The lower active contact LAC may extend vertically from the second surface 100B to the first surface 100A of the substrate 100. The lower active contact LAC may include a metal selected from the group consisting of copper (Cu), aluminum (Al), ruthenium (Ru), cobalt (Co), tungsten (W), and/or molybdenum (Mo).

An upper active region UAR may be provided on the first interlayer insulating layer 110. The upper active region UAR may include upper channel patterns UCH and upper source/drain patterns USD. The upper channel patterns UCH may vertically overlap the lower channel patterns LCH. The upper source/drain patterns USD may vertically overlap the lower source/drain patterns LSD, respectively. The upper channel pattern UCH may be interposed between a pair of upper source/drain patterns USD. The upper channel pattern UCH may electrically and/or physically connect a pair of upper source/drain patterns USD to each other.

The upper channel pattern UCH may include a third semiconductor pattern SP3 and a fourth semiconductor pattern SP4 that are stacked and spaced apart from each other. The third and fourth semiconductor patterns SP3 and SP4 of the upper channel pattern UCH may include the same semiconductor material as the first and second semiconductor patterns SP1 and SP2 of the lower channel pattern LCH described above. Each of the third and fourth semiconductor patterns SP3 and SP4 may be a nanosheet. For example, the upper channel pattern UCH may further include one or more semiconductor patterns that are stacked and spaced apart from the third semiconductor pattern SP3.

At least one dummy channel pattern DSP may be interposed between the lower channel pattern LCH and the upper channel pattern UCH thereabove. A seed layer SDL may be interposed between the dummy channel pattern DSP and the upper channel pattern UCH.

The dummy channel pattern DSP may be spaced apart from the lower and upper source/drain patterns LSD and USD. That is, the dummy channel pattern DSP may not be connected to any source/drain pattern. The dummy channel pattern DSP may include a semiconductor material such as silicon (Si), germanium (Ge), or silicon germanium (SiGe), or may include a silicon-based insulating material such as a silicon oxide or silicon nitride layer. In some embodiments of the inventive concept, the dummy channel pattern DSP may include the silicon-based insulating material.

The upper source/drain patterns USD may be provided on an upper surface of the first interlayer insulating layer 110. Each of the upper source/drain patterns USD may be an epitaxial pattern formed through a selective epitaxial growth (SEG) process. For example, an upper surface of the upper source/drain pattern USD may be higher than an upper surface of the fourth semiconductor pattern SP4 of the upper channel pattern UCH with respect to the substrate.

The upper source/drain patterns USD may be doped with impurities to have a second conductivity type. The second conductivity type may be different from the first conductivity type of the lower source/drain pattern LSD. The second conductivity type may be P type. The upper source/drain patterns USD may include silicon germanium (SiGe) and/or silicon (Si).

A plurality of gate electrodes GE may be provided on a single height cell SHC. Specifically, the gate electrode GE may be provided on the stacked lower and upper channel patterns LCH and UCH (refer to FIG. 4B). When viewed in a plan view, the gate electrode GE may have a bar shape extending in the first direction D1. The gate electrode GE may vertically overlap the stacked lower and upper channel patterns LCH and UCH.

The gate electrode GE may extend in a vertical direction (i.e., third direction D3) from the first surface 100A of the substrate 100 to a gate capping pattern GP. The gate electrode GE may extend in the third direction D3 from the lower channel pattern LCH of the lower active region LAR to the upper channel pattern UCH of the upper active region UAR. The gate electrode GE may extend in the third direction D3 from the first semiconductor pattern SP1 from the lowermost first semiconductor pattern SP1 and the uppermost fourth semiconductor pattern SP4.

The gate electrode GE may be provided on an upper surface, a bottom surface, and both sidewalls of each of the first to fourth semiconductor patterns SP1 and SP4. In other words, a transistor according to some embodiments may include a three-dimensional field effect transistor (e.g., MBCFET or GAAFET) in which the gate electrode GE three-dimensionally surrounds a channel in plan view.

The gate electrode GE may include a lower gate electrode LGE provided in the lower tier of the FEOL layer, i.e. the lower active region LAR, and an upper gate electrode UGE provided in the upper tier of the FEOL layer, i.e. the upper active region UAR. The lower gate electrode LGE and the upper gate electrode UGE may vertically overlap each other. In some embodiments of the inventive concept, the lower gate electrode LGE and the upper gate electrode UGE may be connected to each other. In other words, the gate electrode GE according to some embodiments may be a common gate electrode in which the lower gate electrode LGE on the lower channel pattern LCH and the upper gate electrode UGE on the upper channel pattern UCH are connected to each other.

The lower gate electrode LGE may include a first inner electrode PO1 interposed between the first active pattern AP1 and the first semiconductor pattern SP1, a second inner electrode PO2 interposed between the first semiconductor pattern SP1 and the second semiconductor pattern SP2, and a third inner electrode PO3 interposed between the second semiconductor pattern SP2 and the dummy channel pattern DSP.

The upper gate electrode UGE may include a fourth inner electrode PO4 interposed between the dummy channel pattern DSP (or seed layer SDL) and the third semiconductor pattern SP3, a fifth inner electrode PO5 interposed between the third semiconductor pattern SP3 and the fourth semiconductor pattern SP4, and an outer electrode PO6 on the fourth semiconductor pattern SP4.

A pair of gate spacers GS may be disposed on both sidewalls of the gate electrode GE. Referring to FIG. 4A, a pair of gate spacers GS may be disposed on both sidewalls of the outer electrode PO6. The gate spacers GS may extend in the first direction D1 along the gate electrode GE. Upper surfaces of the gate spacers GS may be higher than upper surfaces of the gate electrode GE. The upper surfaces of the gate spacers GS may be coplanar with the upper surface of the gate capping pattern GP, which will be described later. The gate spacers GS may include at least one of SiCN, SiCON, and SiN. As another example, the gate spacers GS may include a multi-layer made of at least two of SiCN, SiCON, and SiN.

A gate capping pattern GP may be provided on the upper surface of the gate electrode GE. The gate capping pattern GP may extend in the first direction D1 along the gate electrode GE. For example, the gate capping pattern GP may include at least one of SiON, SiCN, SiCON, and/or SiN.

A gate insulating layer GI may be interposed between the gate electrode GE and the first, second, third, and fourth semiconductor patterns SP1, SP2, SP3, and SP4. The gate insulating layer GI may include a silicon oxide layer, a silicon oxynitride layer, and/or a high-k dielectric layer. In some embodiments of the inventive concept, the gate insulating layer GI may include a silicon oxide layer directly covering, overlapping, or on the surface of the semiconductor patterns SP1, SP2, SP3, and SP4 and a high-k dielectric layer on the silicon oxide layer. In other words, the gate insulating layer GI may include a multi-layer of a silicon oxide layer and a high-k dielectric layer.

The high dielectric layer may include a high dielectric constant material that has a higher dielectric constant than the silicon oxide layer. For example, the high dielectric constant material may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium. oxide, lithium oxide, aluminum oxide, lead scandium tantalum oxide, and/or lead zinc niobate.

The lower gate electrode LGE may include a first work function metal pattern on the first and second semiconductor patterns SP1 and SP2. The upper gate electrode UGE may include a second work function metal pattern on the third and fourth semiconductor patterns SP3 and SP4. Each of the first and second work function metal patterns include nitrogen (N) and at least one metal selected from the group consisting of titanium (Ti), tantalum (Ta), aluminum (Al), tungsten (W), molybdenum (Mo), and/or nitrogen (N). The first and second work function metal patterns may have different work functions. The gate electrode GE may include a low-resistance metal (e.g., at least one of tungsten (W), ruthenium (Ru), aluminum (Al), titanium (Ti), and/or tantalum (Ta)) on the first and second work function metal patterns. For example, the outer electrode PO6 may further include the low-resistance metal as well as the second work function metal pattern.

A second interlayer insulating layer 120 may cover, overlap, or be on the upper source/drain patterns USD. An upper surface of the second interlayer insulating layer 120 may be coplanar with an upper surface of each of the upper active contacts UAC, which will be described later.

An upper gate contact UGC may be provided that penetrates the second interlayer insulating layer 120 and the gate capping pattern GP and is electrically connected to the upper gate electrode UGE. Each of the upper active contact UAC and upper gate contact UGC may include a metal selected from the group consisting of copper (Cu), aluminum (Al), ruthenium (Ru), cobalt (Co), tungsten (W), and/or molybdenum (Mo).

A cutting pattern CTP may be provided between the gate electrodes GE adjacent to each other in the first direction D1. The cutting pattern CTP may separate the adjacent gate electrodes GE from each other. The adjacent gate electrodes GE may be spaced apart in the first direction D1 by the cutting pattern CTP. The cutting pattern CTP may have a bar shape or a line shape extending in the second direction D2. The cutting pattern CTP may be an insulating layer formed of one layer or multiple layers.

Vertical vias VT may be provided in the cutting pattern CTP. The vertical via VT may penetrate the cutting pattern CTP in the vertical direction D3 (i.e., third direction D3). The cutting pattern CTP may cover both sidewalls of the vertical via VT. The cutting pattern CTP may extend in the first direction D1 along a bottom surface of the vertical via VT. A width of the vertical via VT may increase as moving away from a bottom surface of the vertical via VT in the vertical direction D3.

A vertical via VT may electrically connect the upper active contact UAC and the lower active contact LAC. The vertical via VT may be provided on one side of the upper active contact UAC and the lower active contact LAC. The upper active contact UAC may extend in the first direction D1 and be electrically connected to an upper portion of the vertical via VT. The lower active contact LAC may extend in the first direction D1 and be electrically connected to a lower portion of the vertical via VT.

The vertical vias VT may include metallic materials. For example, the vertical via VT may include at least one of copper (Cu), aluminum (Al), ruthenium (Ru), cobalt (Co), tungsten (W), and/or molybdenum (Mo).

An insulating structure IS may be provided between the gate electrodes GE adjacent to each other in the first direction D1. The insulating structure IS may separate the adjacent gate electrodes GE from each other. The adjacent gate electrodes GE may be spaced apart in the first direction D1 by the insulating structure IS. The insulating structure IS may have a bar shape or a line shape extending in the second direction D2. The insulating structure IS may include an insulating material. For example, the insulating structure IS may include at least one of SiON, SiCN, SiCON, and/or SiN.

The insulating structure IS may be spaced apart from the vertical via VT in the first direction D1 with the upper source/drain pattern USD and the lower source/drain pattern LSD interposed therebetween.

A level of an upper surface of the insulating structure IS may be equal to or higher than a level of an upper surface of the gate electrodes GE with respect to the substrate. A level of a lower surface of the insulating structure IS may be equal to or lower than a level of a lower surface of the gate electrodes GE with respect to the substrate. The insulating structure IS may penetrate or extend into the gate electrode GE in the vertical direction D3.

The insulating structure IS may extend in the vertical direction D3 (i.e., third direction D3) across the lower active region LAR and the upper active region UAR. The insulating structure IS may extend in the vertical direction D3 (i.e., third direction D3) from the lower active contact LAC to the upper active contact UAC.

The insulating structure IS may be interposed between adjacent upper source/drain patterns USD. The insulating structure IS may be interposed between adjacent lower source/drain patterns LSD. A sidewall of the insulating structure IS may be in direct contact with the upper source/drain pattern USD and lower source/drain pattern LSD.

A level of an upper surface of the insulating structure IS may be equal to or higher than a level of an upper surface of the upper active contact UAC with respect to the substrate. The insulating structure IS may separate the adjacent upper active contacts UAC from each other. A level of a lower surface of the insulating structure IS may be equal to or lower than a level of a lower surface of the lower active contact LAC. A length of the insulating structure IS in the third direction D3 (i.e., third direction D3) may be greater than a length of the cutting pattern CTP and a length of the vertical via VT.

A third interlayer insulating layer 130 may be provided on the second interlayer insulating layer 120. A first metal layer M1 may be provided in the third interlayer insulating layer 130. The first metal layer M1 may include upper interconnections UMI. The first metal layer M1 may further include an upper via UVI. The upper via UVI may electrically connect the upper interconnection UMI to the upper active contact UAC or upper gate contact UGC. Each of the upper interconnection UMI and the upper via UVI may include a metal selected from the group consisting of copper (Cu), aluminum (Al), ruthenium (Ru), cobalt (Co), tungsten (W), and/or molybdenum (Mo).

Additional metal layers (e.g., M2, M3, M4, etc.) may be stacked on the first metal layer M1. The first metal layer M1 and the metal layers (e.g., M2, M3, M4, etc.) on the first metal layer M1 may form a back end of line (BEOL) layer of the semiconductor device. The metal layers (e.g., M2, M3, M4, etc.) on the first metal layer M1 may include routing interconnections for connecting logic cells to each other.

A first lower interlayer insulating layer 200 may be provided below the second surface 100B of the substrate 100. A second lower interlayer insulating layer 210 may be provided below the first lower interlayer insulating layer 200. A backside metal layer BSM may be provided in the second lower interlayer insulating layer 210. The backside metal layer BSM may include lower interconnections LMI. The backside metal layer BSM may further include a lower via LVI. The lower via LVI may electrically connect either the lower active contact LAC or the lower gate contact LGC to the lower interconnection LMI. Each of the lower interconnect LMI and the lower via LVI may include a metal selected from the group consisting of copper (Cu), aluminum (Al), ruthenium (Ru), cobalt (Co), tungsten (W), and/or molybdenum (Mo).

Additional lower metal layers may be deposited below the backside metal layer BSM. In some embodiments of the invention, the lower metal layers may include a power transmission network. The power transmission network may include a wiring network for applying a source voltage (VSS) and a drain voltage (VDD) to the backside metal layer BSM.

A source voltage (VSS) and a drain voltage (VDD) may be applied to the backside metal layer BSM through the power transmission network. Referring back to FIG. 4A, either the source voltage (VSS) or the drain voltage (VDD) may be applied to the lower source/drain pattern LSD through the lower interconnection LMI, the lower via LVI, and the lower active contact LAC. The other of the source voltage (VSS) and the drain voltage (VDD) may be applied from the backside metal layer BSM to the first metal layer M1 through a power tap cell. The voltage applied to the first metal layer M1 through the power tap cell may be applied to the upper source/drain pattern USD, through the upper interconnect UMI, the upper via UVI, and the upper active contact UAC. The power tap cell may be interposed between adjacent single height cells SHC.

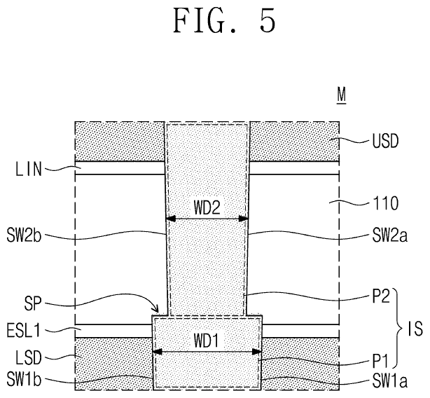

FIG. 5 is an enlarged view of region ‘M’ in FIG. 4B. Hereinafter, with reference to FIG. 5, features of the insulating structure IS according to some embodiments of the inventive concept will be described in detail.

Referring to FIG. 5, the insulating structure IS may include a first portion P1 and a second portion P2 on the first portion P1. The first portion P1 may be provided in the lower active region LAR. The first portion P1 may be adjacent to the lower source/drain pattern LSD. The second portion P2 may be adjacent to the upper source/drain pattern USD.

The first portion P1 may have a first width WD1 in the first direction D1. The second portion P2 may have a second width WD2 in the first direction D2. Each of the first width WD1 and the second width WD2 may increase as a distance from the lower surface of the insulating structure IS increases in the vertical direction D3 (i.e., third direction D3). The first width WD1 may have a maximum value at the highest level of the first portion P1. The second width WD2 may have a maximum value at the highest level of the second portion P2. The second width WD2 may have a minimum value at the lowest level of the second portion P2.

The first width WD1 may be greater than the second width WD2. The maximum value of the first width WD1 may be greater than the minimum value of the second width WD2. In detail, a width of an upper surface of the first portion P1 may be greater than a width of a bottom surface of the second portion P2. Accordingly, the width of the insulating structure IS may change discontinuously between the first portion P1 and the second portion P2. The width of the insulating structure IS may rapidly decrease from the first width WD1 to the second width WD2 between the first portion P1 and the second portion P2.

The first portion P1 may include a first lower sidewall SW1a and a second lower sidewall SW1b facing each other in the first direction D1. The second portion P2 may include a first upper sidewall SW2a and a second upper sidewall SW2b facing each other in the first direction D1. The first lower sidewall SW1a may be spaced apart from the first upper sidewall SW2a in the first direction D1. The second lower sidewall SW1b may be spaced apart from the second upper sidewall SW2b in the first direction D1.

An outer wall of the first portion P1 may include a first step surface SP. The first step surface SP may be an upper surface of the first portion P1 exposed by the second portion P2. The first step surface SP may face and be in contact with the first interlayer insulating layer 110. The first step surface SP may be configured to change the first width WD1 into the second width WD2. The width of the insulating structure IS may change rapidly from the upper portion of the first portion P1 to the lower portion of the second portion P2 due to the first step surface SP. The first step surface SP may extend in the first direction D1. The first step surface SP may be provided on both sides with the second portion P2 interposed therebetween.

The first step surface SP may be provided between the lower region LAR and the upper region UAR. The first step surface SP may be formed in the first interlayer insulating layer 110. The first step surface SP may be disposed between the lower source/drain pattern LSD and the upper source/drain pattern USD. A level of the first step surface SP may be higher than the highest level of the lower source/drain pattern LSD. The level of the first step surface SP may be lower than the lowest level of the upper source/drain pattern USD. The first step surface SP may be disposed between the second semiconductor pattern SP2 and the third semiconductor pattern SP3.

The first step surface SP may be a surface connecting the first lower sidewall SW1a and the first upper sidewall SW2a. The first step surface SP may be a surface connecting the second lower sidewall SW1b and the second upper sidewall SW2b.

Referring again to FIG. 4C, the insulating structure IS penetrating or extending into the gate electrode GE may not have the first step surface SP. The width INT2 (i.e., a second interval INT2) of the insulating structure IS may change continuously. The width INT2 of the insulating structure IS in the first direction D1 on adjacent side surfaces of the upper channel pattern UCH and the lower channel pattern LCH may gradually increase as a distance from a bottom surface of the substrate 100 in the vertical direction D3.

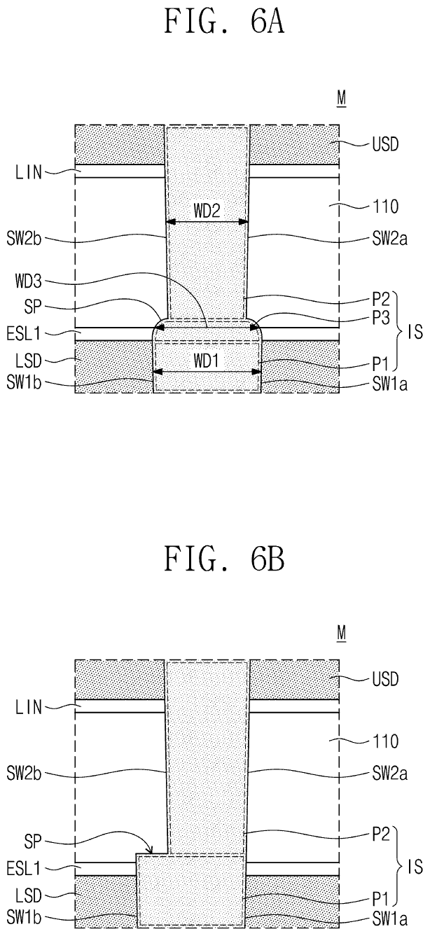

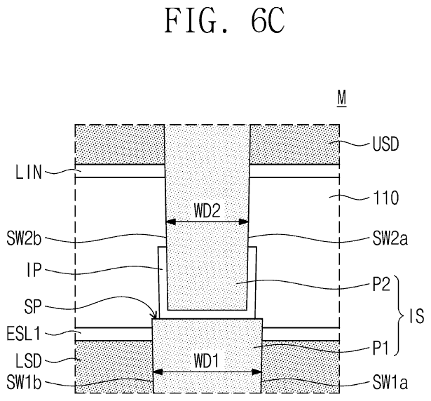

FIGS. 6A, 6B, and 6C are respectively enlarged views of region ‘M’ of FIG. 4B according to other embodiments of the inventive concept. In embodiments to be described later, detailed descriptions of technical features overlapping with those previously described with reference to FIG. 5 will be omitted, and differences will be described in detail.

Referring to FIG. 6A, a third portion P3 may be provided between the first portion P1 and the second portion P2. The third portion P3 may have a third width WD3 in the first direction D1. The third width WD3 may be smaller than the maximum value of the first width WD1 and greater than the minimum value of the second width WD2. The third width WD3 may decrease from the first portion P1 toward the second portion P2.

The third portion P3 may have a curved first outer wall CW. The first outer wall CW may be configured to change the first width WD1 to the second width WD2. The first outer wall CW1 may be provided on both surfaces with the second portion P2 interposed therebetween. A width of the insulating structure IS may gradually change from the first width WD1 to the second width WD2 due to the first outer wall CW. As another example, the third portion P3 may extend along the upper surface of the lower source/drain pattern LSD. In this case, the third width WD3 may be greater than the maximum value of the first width WD1.

Referring to FIG. 6B, a center line of the first portion P1 may be spaced apart from a center line of the second portion P2 in the first direction D1. The center line of the first portion P1 may be offset from the center line of the second portion P2 in the first direction D1. Accordingly, an interval between the first lower sidewall SW1a and the first upper sidewall SW2a in the first direction D1 may be smaller than an interval between the second lower sidewall SW1b and the second upper sidewall SW2b in the first direction D1.

For example, the first lower sidewall SW1a of the first portion P1 may be coplanar with the first upper sidewall SW2a of the second portion P2. As another example, the first lower sidewall SW1a may be spaced apart from the first upper sidewall SW2a in the first direction D1. The first upper sidewall SW2a may be disposed in a direction opposite to the first direction D1 with respect to the first lower sidewall SW1a.

Referring to FIG. 6C, an insulating pattern IP may be interposed between the first portion P1 and the second portion P2. The insulating pattern IP may be in contact with the upper surface of the first portion P1 and the bottom surface of the second portion P2. The insulating pattern IP may cover or overlap at least a portion of the sidewall of the second portion P2. The insulating pattern IP may extend from the bottom surface of the second portion P2 in the third direction D3 along the first and second upper sidewalls SW2a and SW2b. The insulating pattern IP may cover or overlap at least a portion of the upper surface of the first portion P1.

The insulating pattern IP may include an oxide material. The insulating pattern IP may be an oxide layer formed of one layer or multiple layers. The insulating pattern IP may include a material having an etch selectivity different from that of the insulating structure IS. For example, the insulating structure IS may include SiN, and the insulating pattern IP may include SiON. The second width WD2 of the second portion P2 may be reduced by the insulating pattern IP compared to the second width WD2 of FIG. 5.

According to embodiments of the inventive concept, the insulating structure IS may be divided into the first portion P1 and the second portion P2. The width of the upper surface of the first portion P1 may be greater than the width of the bottom surface of the second portion P2. As a result, the first step surface SP may be formed between the first portion P1 and the second portion P2. Accordingly, in a manufacturing process to be described later, the insulating structure IS may be divided into the first portion P1 and the second portion P2. As the first portion P1 and the second portion P2 are formed in order, electrical shorts in the process of etching the upper channel pattern and the lower channel pattern may be minimized.

Furthermore, the vertical vias may be formed in the cutting pattern, thereby reducing the width of the insulating structure. As a result, the three-dimensional semiconductor device according to the inventive concept may improve reliability and improve integration by reducing cell height.

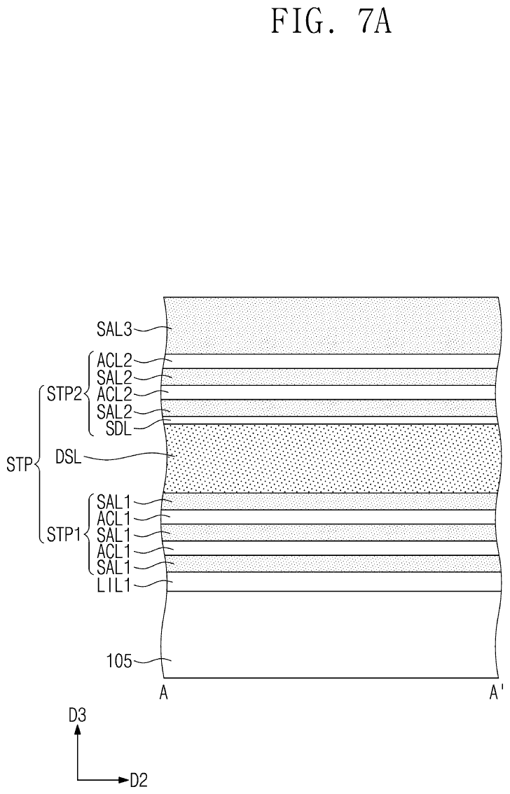

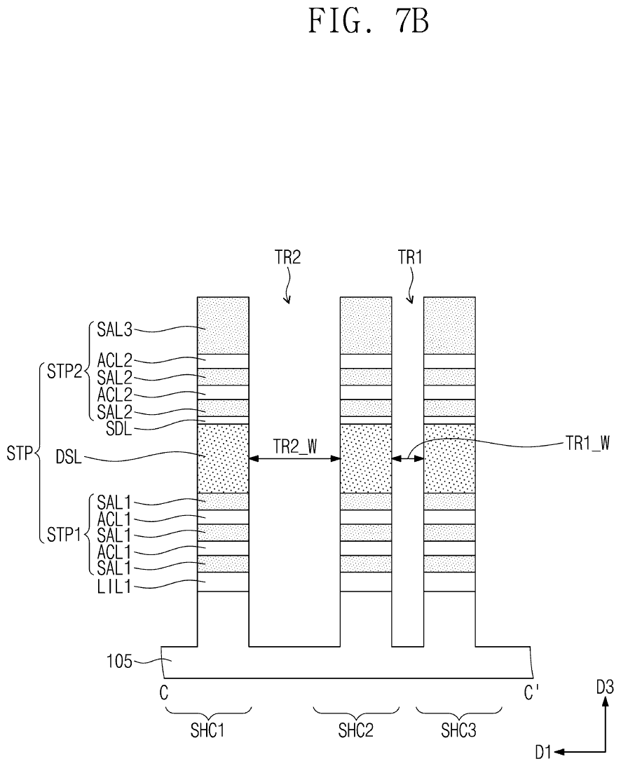

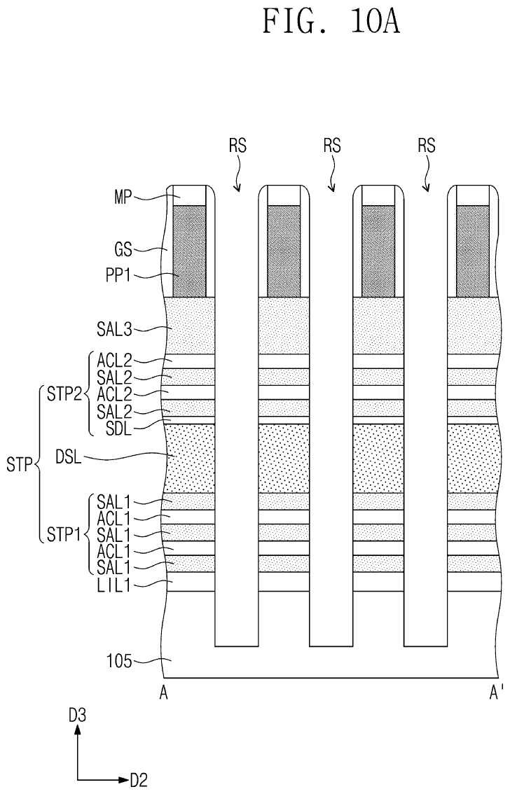

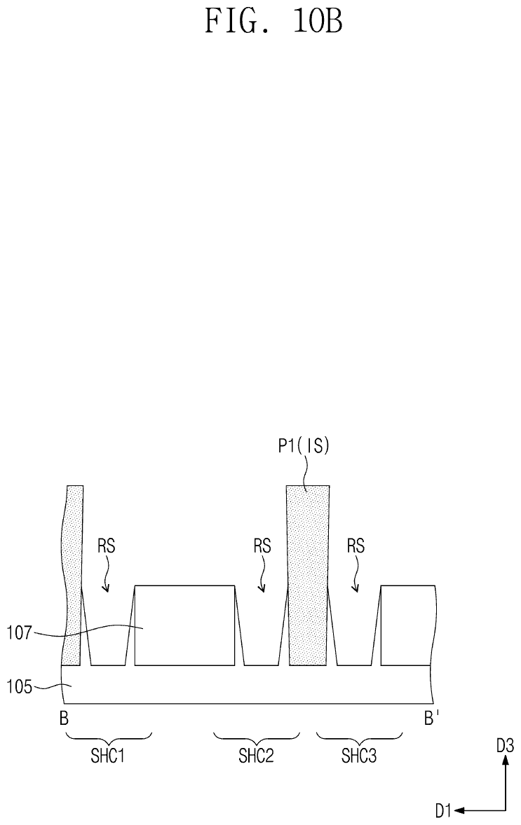

FIGS. 7A, 7B, 8, 9A, 9B, 10A, 10B, 11A, 11B, 12A, 12B, 13A, 13B, 14A, 14B, 15A, 15B, 15C, 16A, 16B, 16C, 17A, 17B, and 17C are cross-sectional views for explaining a method of manufacturing a semiconductor device according to embodiments of the inventive concept. Specifically, FIGS. 7A, 9A, 10A, 12A, 13A, 14A, 15A, 16A, and 17A are cross-sectional views corresponding to line A-A′ in FIG. 3. FIGS. 10B, 11A, 11B, 12B, 13B, 14B, 15B, 16B, and 17B are cross-sectional views corresponding to line B-B′ in FIG. 3. FIGS. 7B, 8, 15C, 16C, and 17C are cross-sectional views corresponding to line C-C′ in FIG. 3.

Referring to FIGS. 7A and 7B, a semiconductor substrate 105 may be provided. The semiconductor substrate 105 may include any one of silicon (Si), germanium (Ge), and silicon-germanium (SiGe). For example, the semiconductor substrate 105 may be a single crystal silicon wafer.

A first lower insulating layer LIL1 may be formed on the semiconductor substrate 105. The first lower insulating layer LIL1 may include a silicon-based insulating material (e.g., silicon oxide) and/or a semiconductor material (Si or SiGe).

First sacrificial layers SAL1 and first active layers ACL1 may be alternately stacked on the first lower insulating layer LIL1. The first sacrificial layers SAL1 may include one of silicon (Si), germanium (Ge), and/or silicon germanium (SiGe), and the first active layers ACL1 may include another one of silicon (Si), germanium (Ge) and/or silicon germanium (SiGe). For example, the first sacrificial layers SAL1 may include silicon germanium (SiGe), and the first active layers ACL1 may include silicon (Si). A concentration of germanium (Ge) in each of the first sacrificial layers SAL1 may be 10 at % to 30 at %.

A separation layer DSL may be formed on the uppermost first sacrificial layer SAL1. In some embodiments of the inventive concept, a thickness of the separation layer DSL may be greater than a thickness of the first sacrificial layer SAL1. The separation layer DSL may include silicon (Si) or silicon germanium (SiGe). When the separation layer DSL includes silicon germanium (SiGe), a concentration of germanium (Ge) in the separation layer DSL may be greater than a concentration of germanium (Ge) in the first sacrificial layer SAL1. For example, the concentration of germanium (Ge) in the separation layer DSL may be 40 at % to 90 at %.

A seed layer SDL may be formed on the separation layer DSL. The seed layer SDL may include the same material as the first active layer ACL1. Second sacrificial layers SAL2 and second active layers ACL2 may be alternately stacked on the seed layer SDL. Each of the second sacrificial layers SAL2 may include the same material as the first sacrificial layer SAL1, and each second active layer ACL2 may include the same material as the first active layer ACL1. The separation layer DSL may be interposed between the first sacrificial layer SAL1 and the seed layer SDL.

A third sacrificial layer SAL3 may be formed on the uppermost second active layer ACL1. A thickness of the third sacrificial layer SAL3 may be greater than a thickness of the second active layer ACL2 and a thickness of the second sacrificial layer SAL2. The third sacrificial layer SAL3 may include the same material as the second sacrificial layer SAL2.

The stacked first and second sacrificial layers SAL1 and SAL2, the first and second active layers ACL1 and ACL2, and the separation layer DSL may be patterned to form a stacked pattern STP. Forming the stacked pattern STP may include forming a hard mask pattern on the uppermost second active layer ACL2, and etching the stacked layers SAL1, SAL2, ACL1, ACL2, SDL, and DSL on the semiconductor substrate 105 using the hard mask pattern as an etch mask. While the stacked pattern STP is formed, an upper portion of the semiconductor substrate 105 may be patterned to form a trench TR defining a single height cell SHC. The stacked pattern STP may have a bar shape or a line shape extending in the second direction D2.

The stacked pattern STP may include a lower stacked pattern STP1 on the first lower insulating layer LIL1, an upper stacked pattern STP2 on the lower stacked pattern STP1, and a separation layer DSL between the lower and upper stacked patterns STP1 and STP2. The lower stacked pattern STP1 may include first sacrificial layers SAL1 and first active layers ACL1 that are alternately stacked. The upper stacked pattern STP2 may include a seed layer SDL and second sacrificial layers SAL2 and second active layers ACL2 alternately stacked on the seed layer SDL.

The trench TR may include a first trench TR1 and a second trench TR2, as illustrated in FIG. 7B. The first trench TR1 may be formed between the second single height cell SHC2 and the third single height cell SHC3. The second trench TR2 may be formed between the first single height cell SHC1 and the second single height cell SHC2. A width TR2_W of the second trench TR2 may be greater than a width TR1_W of the first trench TR1. An interval between the stacked pattern STP on the first single height cell SHC1 and the stacked pattern STP on the second single height cell SHC2 is the distance between the stacked pattern STP on the second single height cell SHC2 may be greater than an interval between the stacked pattern STP on the second single height cell SHC2 and the stacked pattern on the third single height cell SHC3.

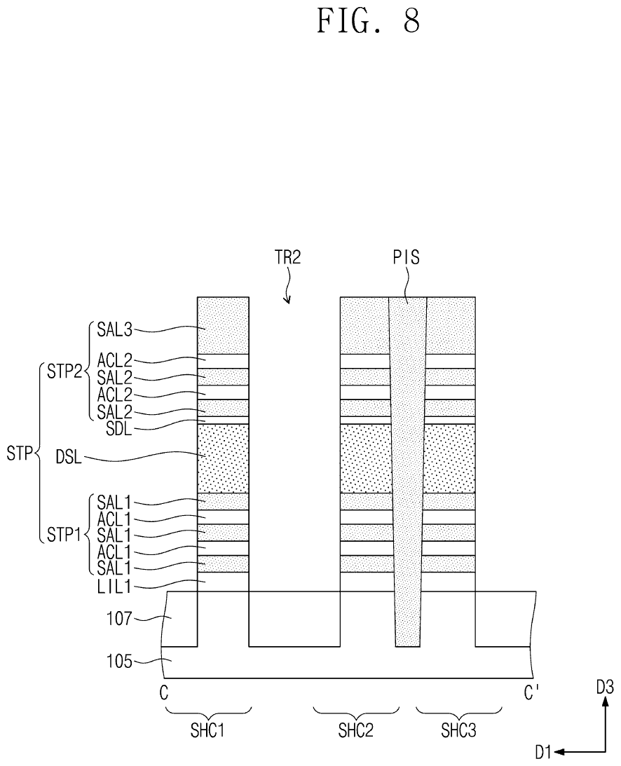

Referring to FIG. 8, a preliminary insulating structure PIS may be formed on the semiconductor substrate 105 to partially or completely fill the first trench TR1. Specifically, a mask layer exposing the first trench TR1 may be formed on a front surface of the semiconductor substrate 105. The first trench TR1 may be partially or completely filled with an insulating material. The insulating material may be recessed until an upper surface of the third sacrificial layer SAL3 is exposed, to form the preliminary insulating structure PIS. The process of recessing the insulating material may be a wet etching process. The mask layer may then be removed.

A device isolation layer 107 may be formed on the semiconductor substrate 105 to partially or completely fill a lower portion of the second trench TR2. Specifically, an insulating layer covering or overlapping the stacked patterns STP may be formed on the front surface of the semiconductor substrate 105. The insulating layer may be recessed until the stacked patterns STP are exposed, to form the device isolation layer 107. An upper surface of the device isolation layer 107 may be coplanar with an upper surface of the semiconductor substrate 105.

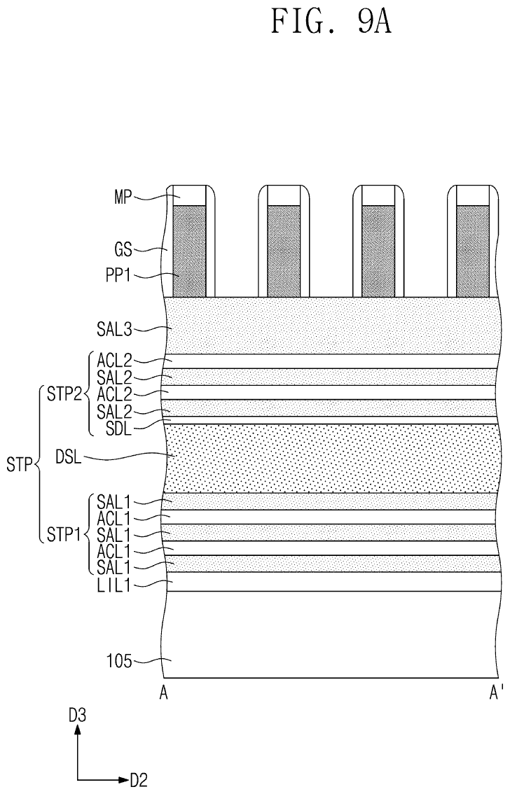

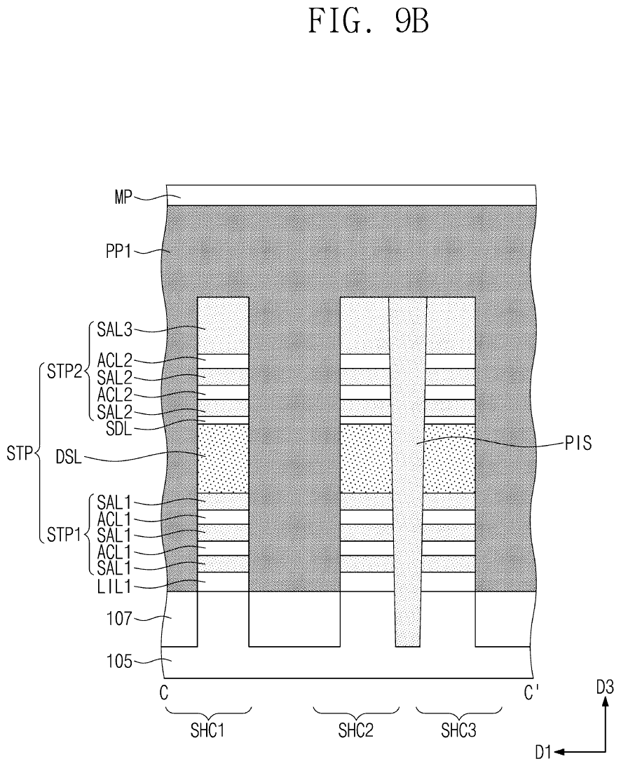

Referring to FIGS. 9A and 9B, a plurality of first sacrificial patterns PP1 may be formed across the stacked pattern STP. Each of the first sacrificial patterns PP1 may be formed in a line shape extending in the first direction D1. Specifically, forming the first sacrificial pattern PP1 may include forming a sacrificial layer on the front surface of the semiconductor substrate 105, forming a hard mask pattern MP on the sacrificial layer, and patterning the sacrificial layer using the hard mask pattern MP as an etch mask. The sacrificial layer may include amorphous silicon and/or polysilicon.

A pair of gate spacers GS may be formed on both sidewalls of the first sacrificial pattern PP1, respectively. Specifically, a spacer layer may be formed conformally on the entire surface of the semiconductor substrate 105. The spacer layer may cover or overlap the first sacrificial pattern PP1 and the hard mask pattern MP. For example, the spacer layer may include at least one of SiCN, SiCON, and/or SiN. The spacer layer may be anisotropically etched, to form the gate spacers GS.

Referring to FIGS. 10A and 10B, an etching process may be performed on the stacked pattern STP using the gate spacers GS and the hard mask pattern MP as an etch mask. Through the etching process, a recess RS may be formed between adjacent first sacrificial patterns PP1. The stacked pattern STP may be formed in the shape of a vertical bar by the recess RS.

An upper portion of the preliminary insulating structure PIS may be removed through the etching process to form the first portion P1. The highest level of the first portion P1 may be lower than a level of a bottom surface of the seed layer SDL. A level of an upper surface of a first portion P1 may be disposed between an upper surface of the dummy channel pattern DSP and a lower surface of the dummy channel pattern DSP.

In some embodiments of the inventive concept, when the separation layer DSL includes silicon germanium (SiGe), the separation layer DSL may be replaced with a silicon-based insulating material to form a dummy channel pattern DSP. The separation layer DSL exposed by the recess RS may be selectively removed, and a silicon-based insulating material (e.g., silicon nitride) may be partially or completely filled in a region where the separation layer DSL has been removed.

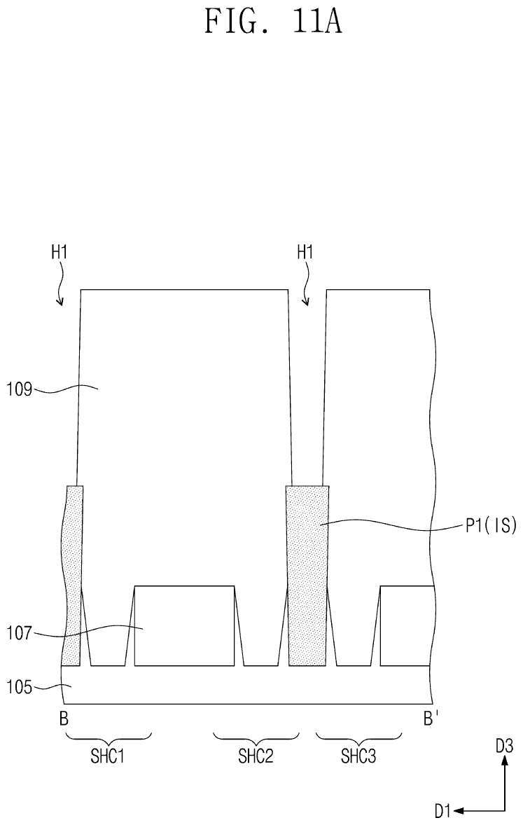

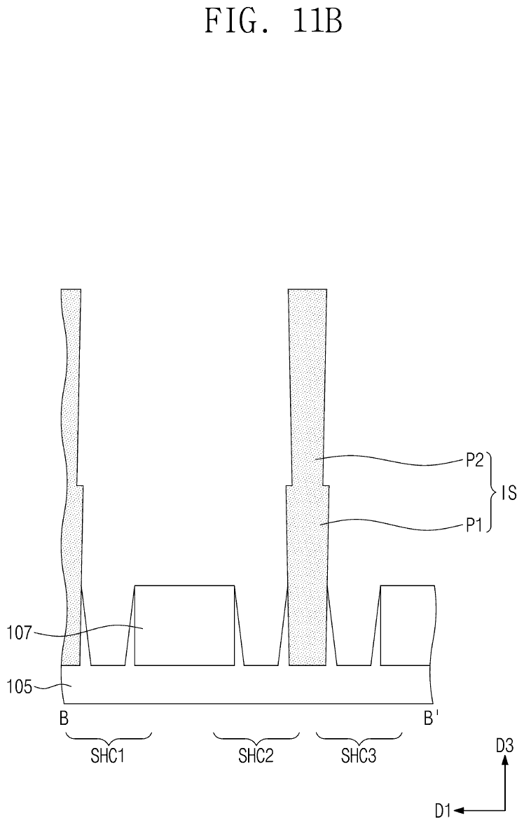

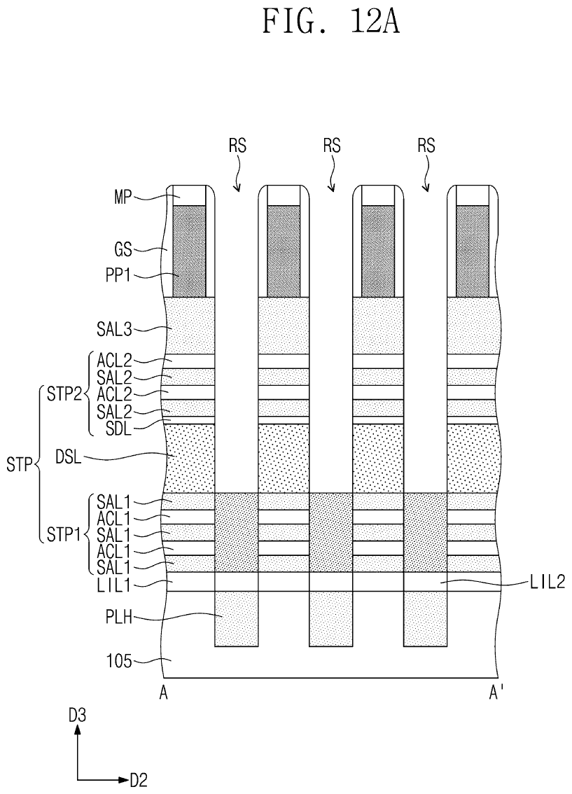

Referring to FIG. 11A, a sacrificial layer 109 may be formed on the first portion P1. A patterning process may be performed on the sacrificial layer 109 to etch the sacrificial layer 109 to form first holes H1. A portion of the upper surface of the first portion P1 may be exposed by the first hole H1. A width of the first hole H1 may decrease as the first hole H1 approaches the upper surface of the first portion P1.

Referring to FIG. 11B, the second portion P2 may be formed by partially or completely filling the first hole H1 with an insulating material. The second portion P2 may vertically overlap the first portion P1. The second portion P2 may include the same material as the first portion P1. After the second portion P2 is formed, the sacrificial layer 109 may be removed to form the recess RS again.

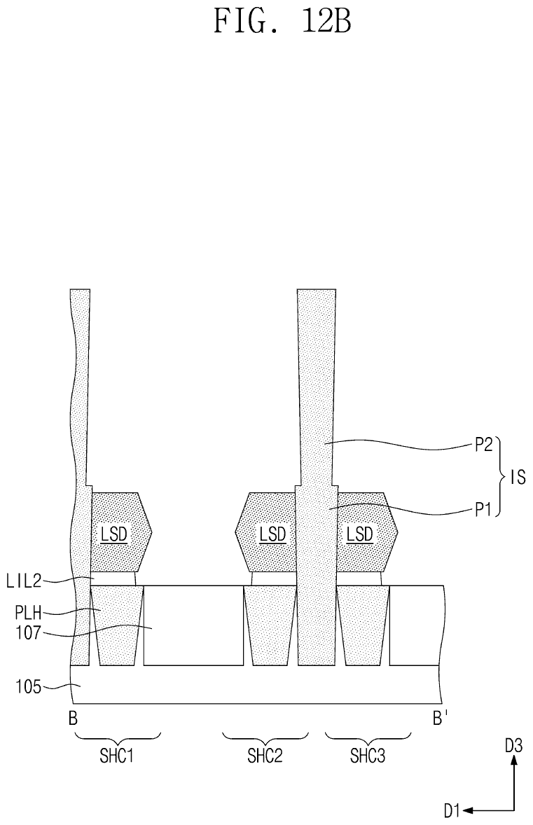

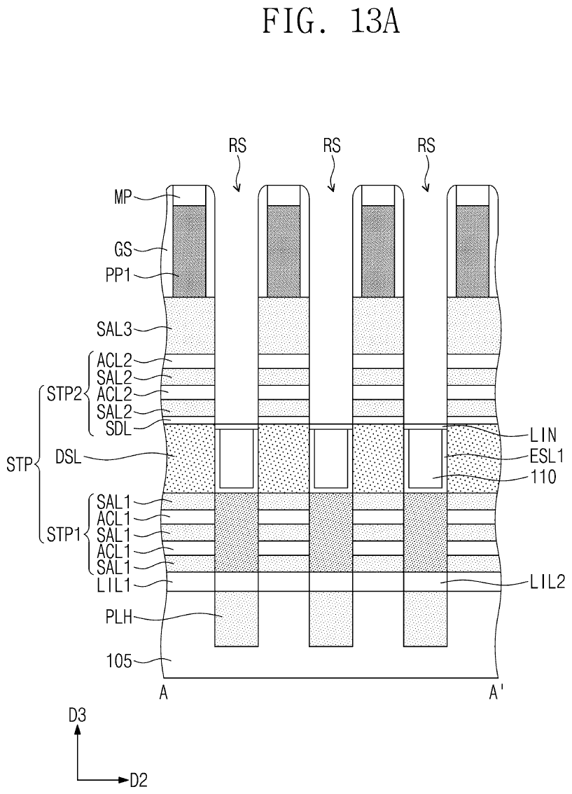

Referring to FIGS. 12A and 12B, sacrificial contact patterns PLH may be formed in the semiconductor substrate 105 exposed through the recess RS. The sacrificial contact patterns PLH may be formed in a contact shape. The sacrificial contact patterns PLH may be arranged in the second direction D2. The sacrificial contact patterns PLH may include a material that has etch selectivity with the semiconductor substrate 105, for example, silicon-germanium (SiGe). The sacrificial contact patterns PLH may be formed using an epitaxial growth process. The recess RS may expose the sacrificial contact pattern PLH. In other words, the recess RS may overlap with the sacrificial contact pattern PLH.

A second lower insulating layer LIL2 may be formed on the sacrificial contact pattern PLH in the recess RS. An upper surface of the second lower insulating layer LIL2 may be coplanar with an upper surface of the first lower insulating layer LIL1. The second lower insulating layer LIL2 may be formed of a silicon-based insulating material (e.g., silicon oxide, silicon oxynitride, or silicon nitride). In some embodiments, the second lower insulating layer LIL2 may be formed of the same material as the device isolation layer 107.

A lower source/drain pattern LSD may be formed on the second lower insulating layer LIL2 in the recess RS. Specifically, the lower source/drain pattern LSD may be formed by performing a first SEG process using the exposed sidewall of the lower stacked pattern STP1 by the recess RS as a seed layer. The lower source/drain pattern LSD may be grown using the first active layers ACL1 exposed by the recess RS as a seed. As an example, the first SEG process may include a chemical vapor deposition (CVD) process or a molecular beam epitaxy (MBE) process.

During the first SEG process, impurities may be injected in-situ into the lower source/drain pattern LSD. As another example, after the lower source/drain pattern LSD is formed, impurities may be injected into the lower source/drain pattern LSD. The lower source/drain pattern LSD may be doped to have a first conductivity type (e.g., N-type).

A first active layers ACL1 interposed between a pair of lower source/drain patterns LSD may form a lower channel pattern LCH. That is, the first and second semiconductor patterns SP1 and SP2 of the lower channel pattern LCH may be formed from the first active layers ACL1. The lower channel patterns LCH and lower source/drain patterns LSD may form a lower active region LAR, which is a bottom tier of a three-dimensional device.

The lower source/drain pattern LSD may be formed to completely fill a space between the pair of lower channel patterns LCH. In other words, the first SEG process may be performed for a sufficient time until the lower source/drain pattern LSD fills the space between the pair of lower channel patterns LCH and electrically and/or physically connects the lower channel patterns LCH to each other.

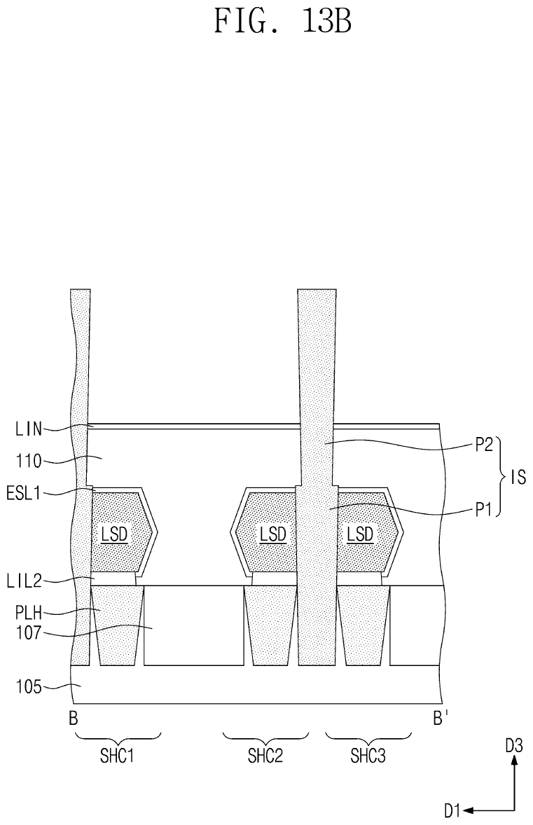

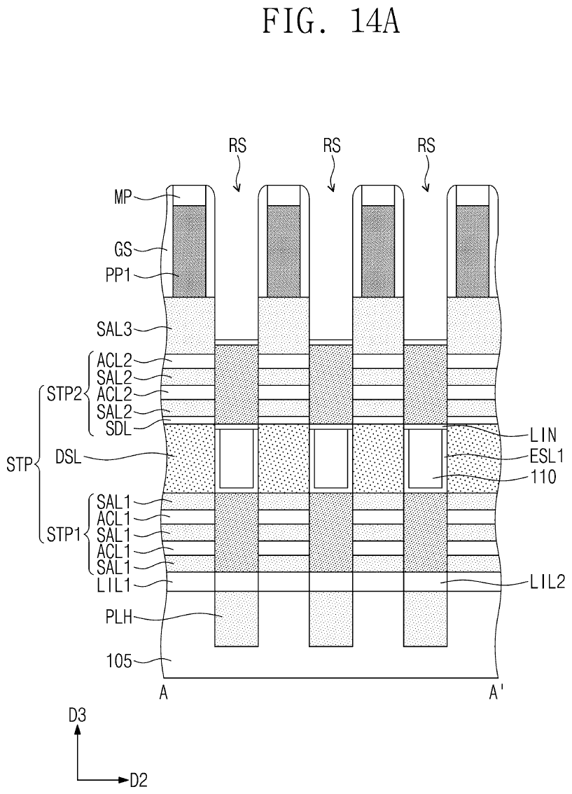

Referring to FIGS. 13A and 13B, the first interlayer insulating layer 110 may be formed to cover or overlap the lower source/drain pattern LSD. As an example, prior to forming the first interlayer insulating layer 110, a first insulating layer ESL1 may be further formed to conformally cover the lower source/drain pattern LSD. The first insulating layer ESL1 may be an insulating layer formed of one layer or multiple layers.

In the recess RS, the first interlayer insulating layer 110 may cover, overlap, or be on a sidewall of the upper stacked pattern STP2. Thereafter, an upper portion of the first interlayer insulating layer 110 may be removed to expose the sidewall of the upper stacked pattern STP2 in the recess RS again. A first liner layer LIN may be formed to conformally cover the first interlayer insulating layer 110. The first liner layer LIN may be an insulating layer formed of one layer or multiple layers.

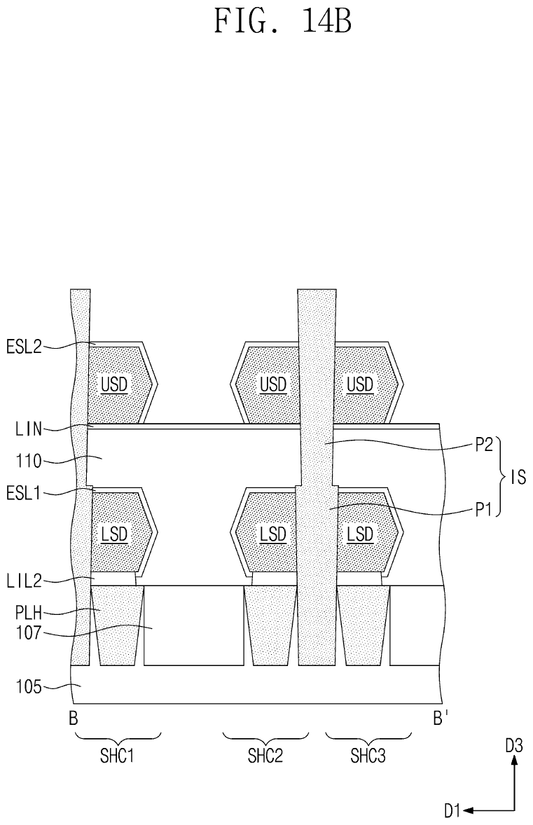

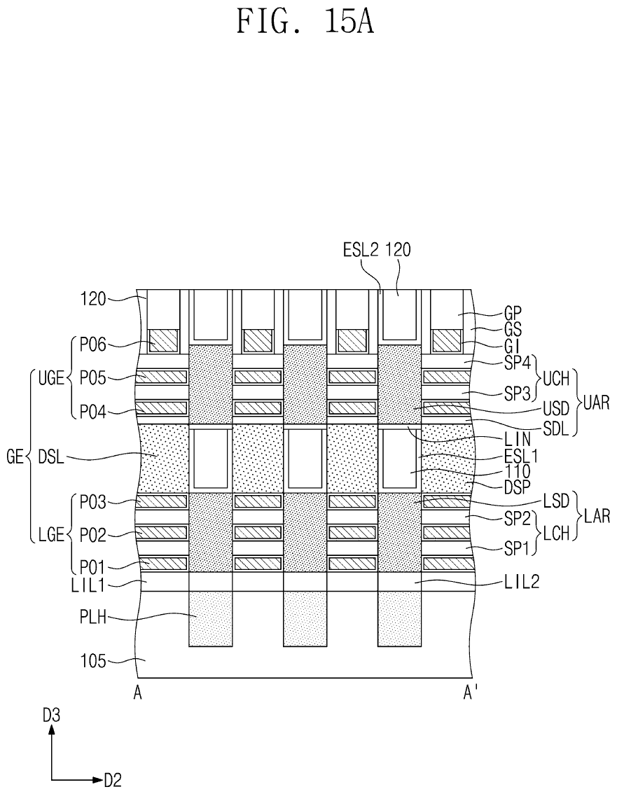

Referring to FIGS. 14A and 14B, an upper source/drain pattern USD may be formed on the exposed sidewall of the upper stacked pattern STP2. Specifically, a second SEG process may be performed using the sidewall exposed by the recess RS of the upper stacked pattern STP2 as a seed layer to form the upper source/drain pattern USD. The upper source/drain pattern USD may be grown using the second active layers ACL2 exposed by the recess RS as a seed. The upper source/drain pattern USD may be doped to have a second conductivity type (e.g., P type) different from the first conductivity type.

The second active layers ACL2 interposed between a pair of upper source/drain patterns USD may form an upper channel pattern UCH. That is, the third and fourth semiconductor patterns SP3 and SP4 of the upper channel pattern UCH may be formed from the second active layers ACL2. The upper channel patterns UCH and upper source/drain patterns USD may form the upper active region UAR, which is a top tier of the three-dimensional device. The second SEG process may also be performed for a sufficient time so that the upper source/drain pattern USD completely fills a space between the pair of upper channel patterns UCH. The second insulating layer ESL2 may be conformally formed on the upper source/drain pattern USD. The second insulating layer ESL2 may be an insulating layer formed of one layer or multiple layers.

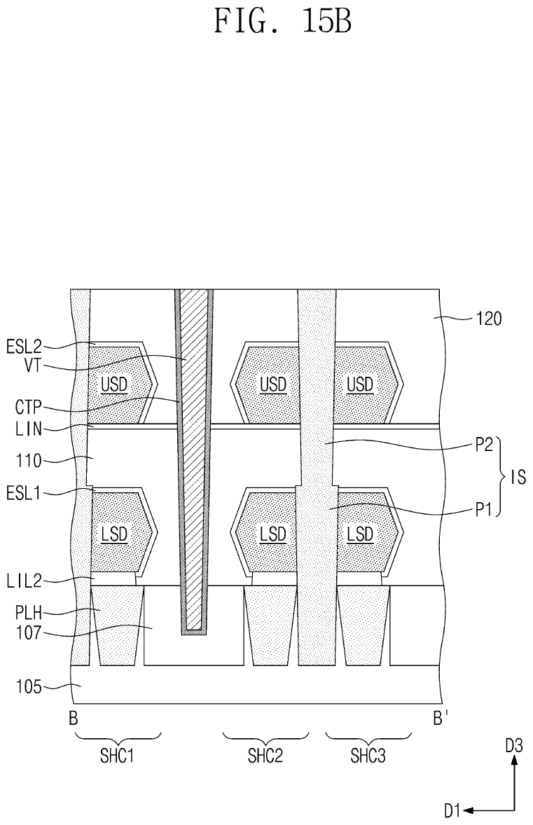

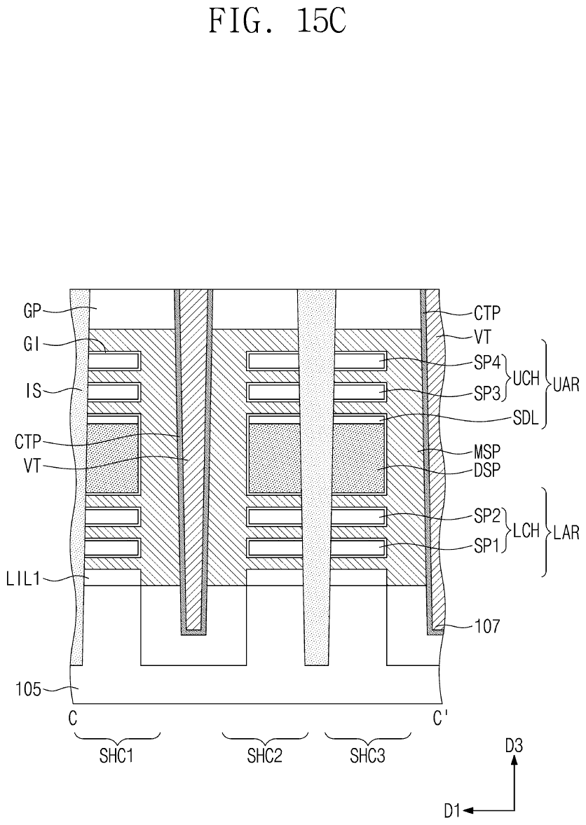

Referring to FIGS. 15A, 15B, and 15C, a second interlayer insulating layer 120 may be formed on the second insulating layer ESL2 to partially or completely fill the recess RS. As an example, the second interlayer insulating layer 120 may include a silicon oxide layer.

The second interlayer insulating layer 120 may be planarized until an upper surface of the first sacrificial pattern PP1 is exposed. Planarization of the second interlayer insulating layer 120 may be performed using an etch back or chemical mechanical polishing (CMP) process. During the planarization process, all hard mask patterns MP on the first sacrificial pattern PP1 may be removed. As a result, an upper surface of the second interlayer insulating layer 120 may be coplanar with an upper surfaces of the first sacrificial pattern PP1 and upper surfaces of the gate spacers GS.

The exposed first sacrificial pattern PP1 may be selectively removed. Removing the first sacrificial pattern PP1 may include wet etching using an etchant that selectively etches polysilicon. The first sacrificial pattern PP1 may be removed to expose the first and second sacrificial layers SAL1 and SAL2.

The etching process may be performed to selectively etch the first and second sacrificial layers SAL1 and SAL2, and thus the first and second sacrificial layers SAL1 and SAL2 may be removed while leaving the first, second third, and fourth semiconductor patterns SP1, SP2, SP3, and SP4 and the dummy channel pattern DSP intact. The etching process may have a high etch rate for silicon germanium. For example, the etching process may have a high etch rate for silicon germanium with a germanium concentration greater than 10 at %.

A gate insulating layer GI may be conformally formed in a region where the first sacrificial pattern PP1 and the first and second sacrificial layers SAL1 and SAL2 have been removed. A gate electrode GE may be formed on the gate insulating layer GI. Forming the gate electrode GE may include forming first, second, third, fourth, and fifth inner electrodes PO1, PO2, PO3, PO4, and PO5 between the first, second, third, and fourth semiconductor patterns SP1, SP2, SP3, and SP4, and forming an outer electrode PO6 in a region from which the first sacrificial pattern PP1 has been removed.

The gate electrode GE may be recessed, reducing a height of the gate electrode GE. A gate capping pattern GP may be formed on the recessed gate electrode GE. A planarization process may be performed on the gate capping pattern GP so that an upper surface of the gate capping pattern GP is coplanar with an upper surface of the second interlayer insulating layer 120.

A cutting pattern CTP may be formed between the first single height cell SHC1 and the second single height cell SHC2. The cutting pattern CTP may extend into the device isolation layer 107 through the gate capping pattern GP and the gate electrode GE. Forming the cutting pattern CTP may include forming a cutting mask pattern on the gate capping pattern GP and the second interlayer insulating layer 120, etching the gate capping pattern GP and the second interlayer insulating layer 120 using the cutting mask pattern as an etch mask to form a cutting hole exposing the device isolation layer 107, and conformally forming an insulating material in the cutting hole.

A vertical via VT may be formed in the cutting pattern CTP. Forming a vertical via VT may include partially or completely filling a metal material into the cutting hole conformally covered with or overlapped by the insulating material. For example, the metal material may be formed of a metal selected from the group consisting of copper (Cu), aluminum (Al), ruthenium (Ru), cobalt (Co), tungsten (W), and/or molybdenum (Mo).

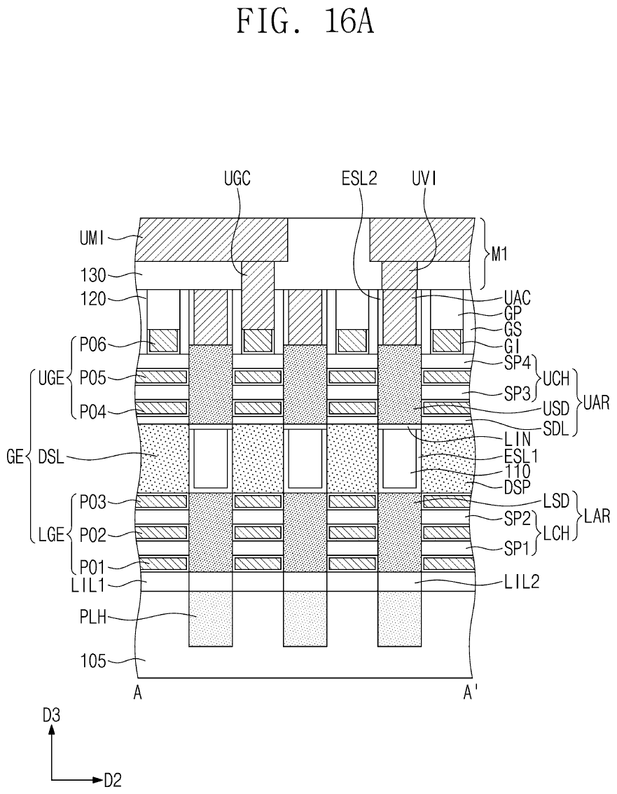

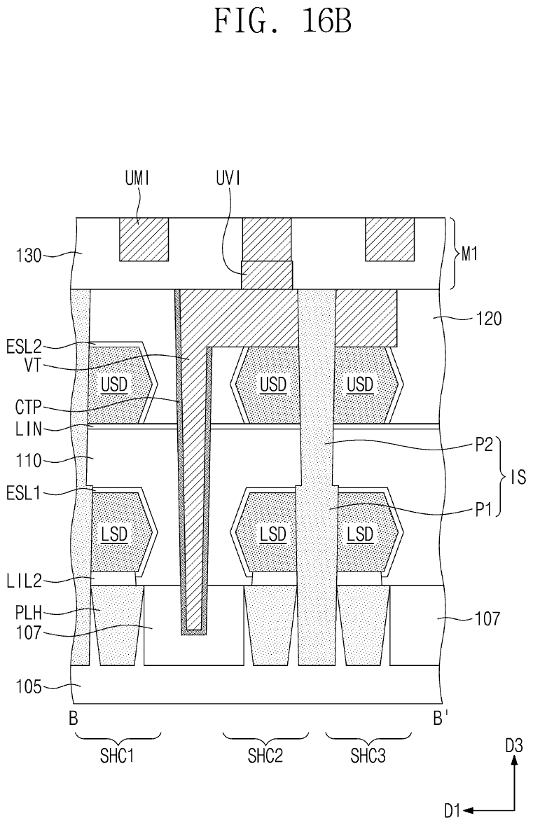

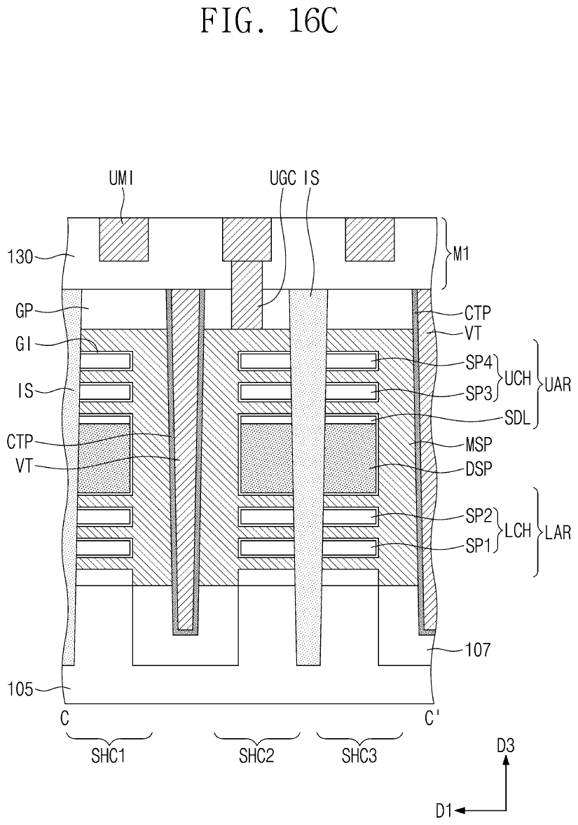

Referring to FIGS. 16A, 16B, and 16C, upper active contacts UAC may be formed through the second interlayer insulating layer 120 and respectively electrically connected to the upper source/drain patterns USD. The upper active contact UAC may extend in the first direction D1 and be in contact with an upper portion of the vertical via VT. To this end, portion of the cutting pattern CTP may be removed. An upper gate contact UGC may be formed through the second interlayer insulating layer 120 and the gate capping pattern GP and connected to the gate electrode GE. For example, each of the upper active contact UAC and upper gate contact UGC may formed of a metal selected from the group consisting of copper (Cu), aluminum (Al), ruthenium (Ru), cobalt (Co), tungsten (W), and/or molybdenum (Mo).

A third interlayer insulating layer 130 may be formed to cover, or overlap the second interlayer insulating layer 120. A first metal layer M1 including upper interconnections UMI may be formed in the third interlayer insulating layer 130. Upper vias UVI may be formed to electrically connect the first metal layer M1 to the gate contacts GC and the upper active contacts UAC. A BEOL layer including additional metal layers (e.g., M2, M3, M4, etc.) may be formed on the first metal layer M1.

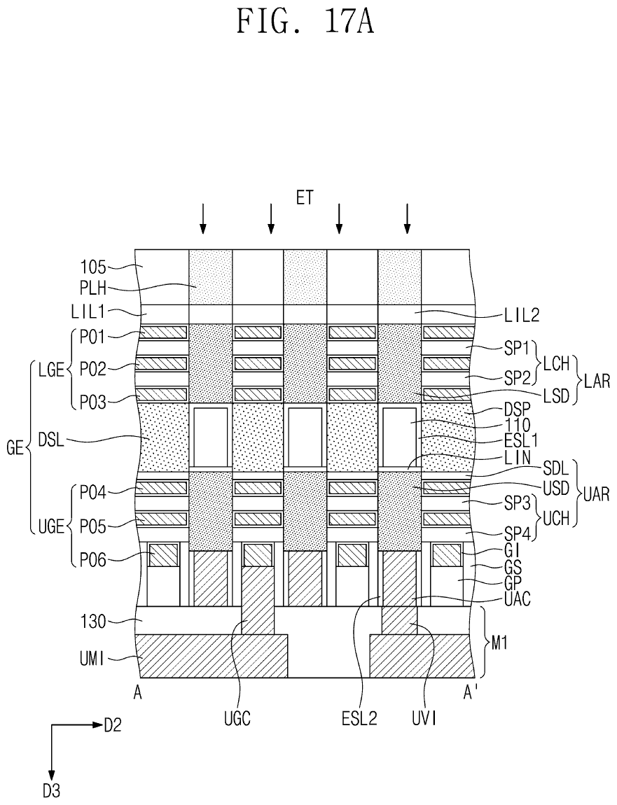

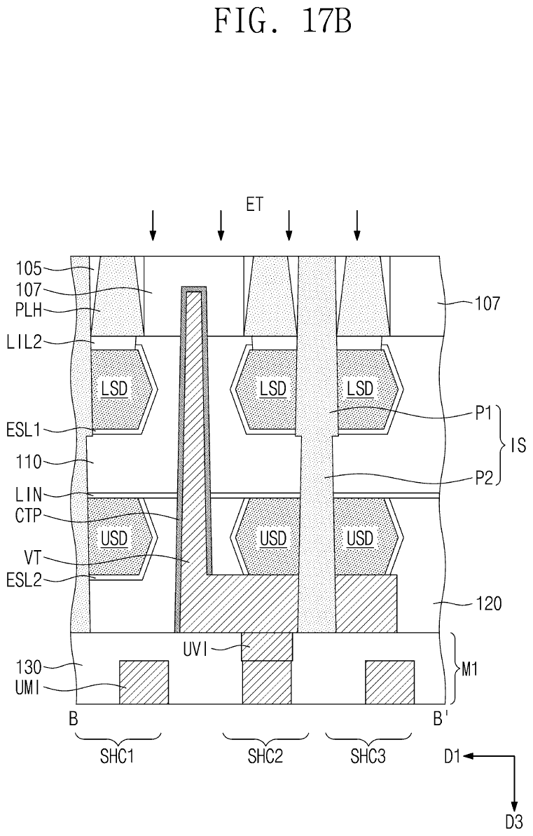

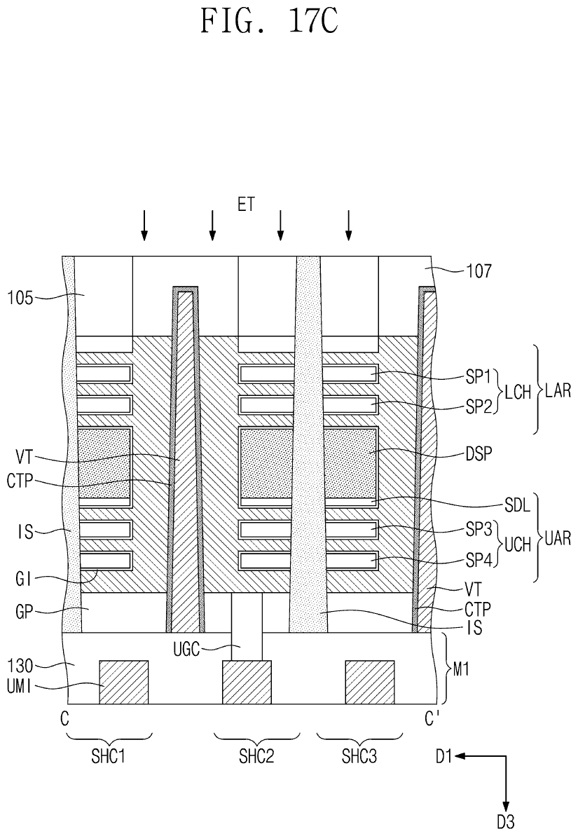

Referring to FIGS. 17A, 17B, and 17C, the semiconductor substrate 105 may be turned over so that the back surface of the semiconductor substrate 105 is exposed. An etching process may be performed on the back surface of the semiconductor substrate 105, and thus a height of the semiconductor substrate 105 may be reduced. A planarization process may be performed on the back surface of the semiconductor substrate 105 until the upper surfaces of the sacrificial contact patterns PLH are exposed.

Referring again to FIGS. 4A, 4B, and 4C, the sacrificial contact pattern PLH may be replaced with the lower active contact LAC. Specifically, the sacrificial contact pattern PLH may be selectively removed. An etching process may be performed on a region from which the sacrificial contact pattern PLH has been removed to expose the lower source/drain pattern LSD. A lower active contact LAC connected to the exposed lower source/drain pattern LSD may be formed. The lower active contact LAC may be formed using a self-alignment manner using the sacrificial contact pattern PLH.

The semiconductor substrate 105 may be replaced with the substrate 100. The substrate 100 may be an insulating substrate including a silicon-based insulating material (e.g., silicon oxide and/or silicon nitride). As another example, the semiconductor substrate 105 may not be replaced with the substrate 100.

A first lower interlayer insulating layer 200 may be formed on the substrate 100. A connection portion electrically connecting the lower active contact LAC and the vertical via VT may be formed in the first lower interlayer insulating layer. Accordingly, the lower active contact LAC may extend in the first direction D1 and be in contact with a lower portion of the vertical via VT. To this end, the cutting pattern CTP may be partially removed.

A second lower interlayer insulating layer 210 may be formed under the first lower interlayer insulating layer 200. A backside metal layer BSM may be formed in the second lower interlayer insulating layer 210. The backside metal layer BSM may include lower interconnections LMI. Lower vias LVI may be formed to electrically connect the backside metal layer BSM to the lower active contact LAC and the lower gate contact LGC. Additional backside metal layers may be formed on the backside metal layer BSM. In some embodiments of the invention, the backside metal layers may include a power transmission network.

In embodiments to be described later, detailed descriptions of technical features overlapping with those previously described with reference to FIGS. 3 and 4A, 4B, and 4C will be omitted, and differences will be described in detail.

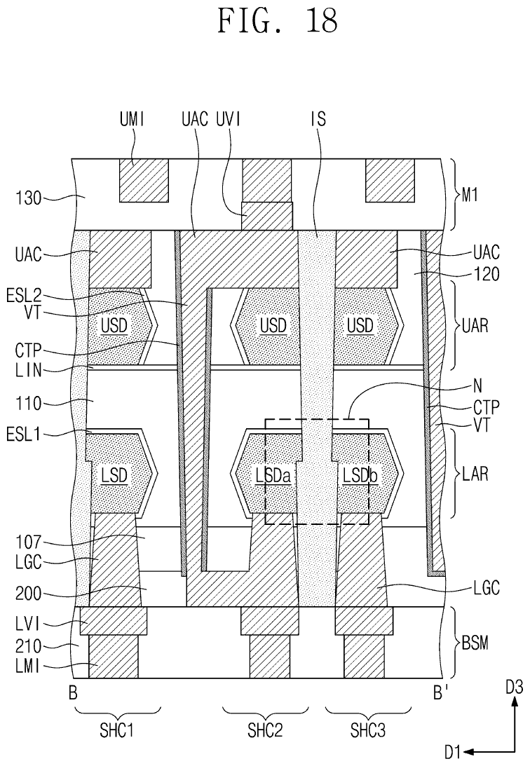

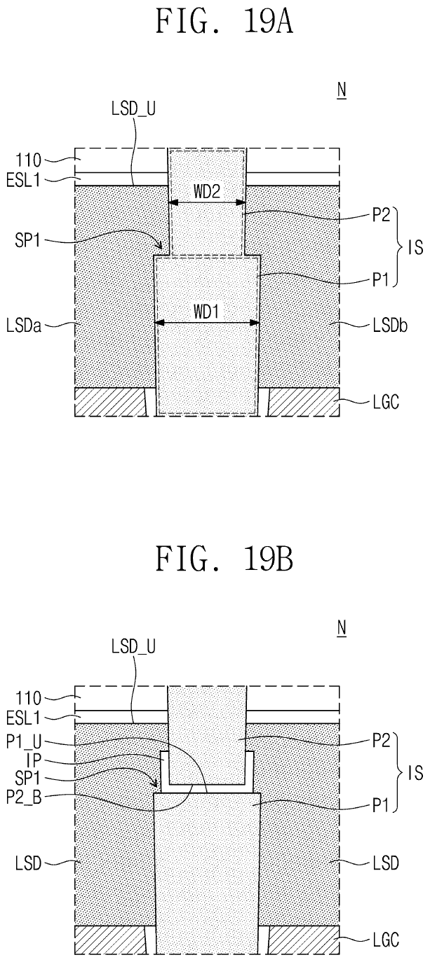

FIG. 18 is a cross-sectional view taken along line B-B′ of FIG. 3 according to some embodiments of the inventive concept. FIGS. 19A and 19B are respectively enlarged views of region ‘N’ of FIG. 18 according to some embodiments of the inventive concept.

Referring to FIGS. 18 and 19A, the first step surface SP1 may be formed in the lower source/drain pattern LSD. The first step surface SP1 may be formed to face the lower source/drain pattern LSD. A level of the first step surface SP1 may be lower than a level of an upper surface LSD_U of the lower source/drain pattern LSD. The level of the first step surface SP1 may be higher than a level of a bottom surface of the lower source/drain pattern LSD.

The lower portion of the second portion P2 may be buried in the lower source/drain pattern LSD. One sidewall of the first portion P1 may be spaced apart from one sidewall of the second portion P2 in the horizontal direction D1. At least a portion of the sidewall of the second portion P2 may be in direct contact with the lower source/drain pattern LSD.

As another example, referring to FIG. 6B, a center line of the first portion P1 may be spaced apart from a center line of the second portion P2 in the first direction. As another example, referring to FIG. 6A, a third portion P3 may be provided between the first portion P1 and the second portion P2. The third portion P3 may be a portion that changes the first width WD1 to the second width WD2.

Referring to FIG. 19B, an insulating pattern IP may be interposed between the first portion P1 and the second portion P2. The insulating pattern IP may be in contact with an upper surface P1_U of the first portion P1 and a bottom surface P2_B of the second portion P2. The insulating pattern IP may extend from the bottom surface P2_B of the second portion P2 in the third direction D3 along the sidewall of the second portion P2.

An insulating pattern IP may be provided in the lower source/drain pattern LSD. The highest level of the insulation pattern IP may be lower than the level of the upper surface LSD_U of the lower source/drain pattern LSD. An outer wall of the insulating pattern IP may be in direct contact with the lower source/drain pattern LSD. As another example, an upper surface of the insulating pattern IP may extend along the sidewall of the second portion P2 to form a coplanar surface with the upper surface of the first interlayer insulating layer 110.

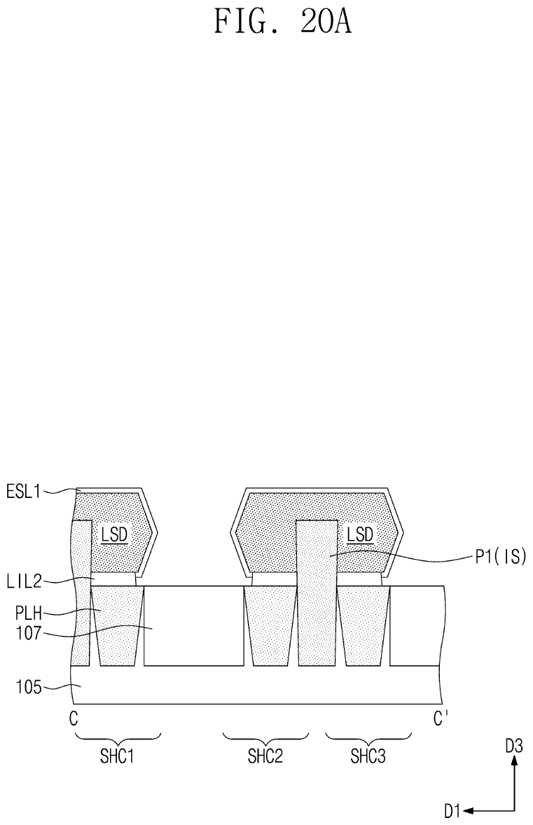

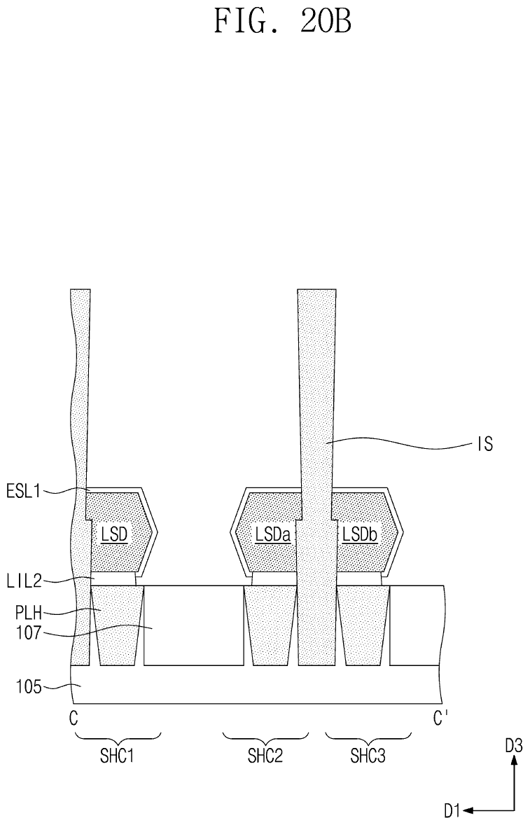

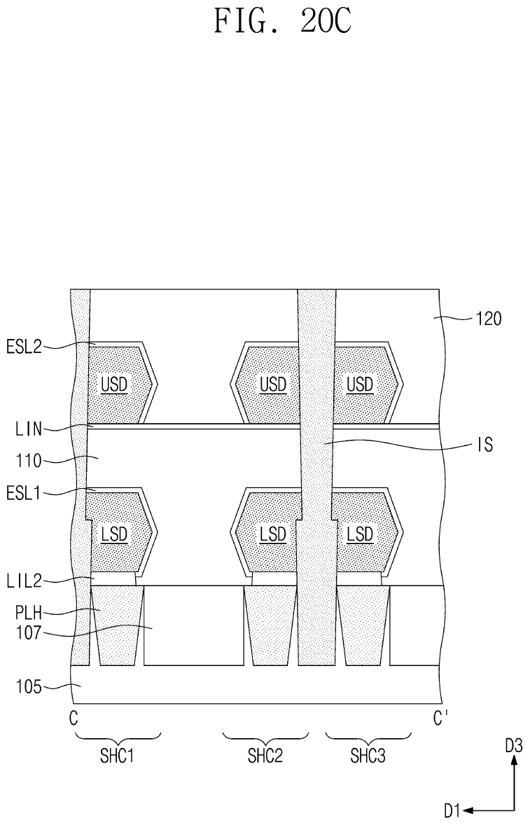

FIGS. 20A, 20B, and 20C are cross-sectional views for explaining a method of manufacturing a semiconductor device according to some embodiments of the inventive concept. FIGS. 20A, 20B, and 20C are cross-sectional views for explaining the manufacturing method of the semiconductor device according to FIG. 19A. FIG. 20A may be a process following the manufacturing process corresponding to FIG. 10B.

Referring to FIG. 20A, sacrificial contact patterns PLH may be formed in the semiconductor substrate 105 exposed through the recess RS. A second lower insulating layer LIL2 may be formed on the sacrificial contact pattern PLH in the recess RS.

A lower source/drain pattern LSD may be formed on the second lower insulating layer LIL2 in the recess RS. Specifically, the lower source/drain pattern LSD may be formed by performing a first SEG process using the exposed sidewall of the lower stacked pattern STP1 by the recess RS as a seed layer.

Upper portions of the lower source/drain patterns LSD adjacent to each other with the first portion P1 therebetween may be in contact with each other to form an integral body. The lower source/drain pattern LSD may cover the upper surface and both sidewalls of the first portion P1. The upper portion of the first portion P1 may be buried in the lower source/drain pattern LSD. The upper surface of the lower source/drain pattern LSD may extend in the first direction D1. The upper surface of the lower source/drain pattern LSD may have a convex profile in the vertical direction D3. The first insulating layer ESL1 may be conformally formed on the lower source/drain pattern LSD.

Referring to FIG. 20B, the second portion P2 may be formed on the first portion P1. A lower portion of the second portion P2 may be buried in the lower source/drain pattern LSD. The second portion P2 may vertically overlap the first portion P1. Forming the second portion P2 may include forming a sacrificial layer on the front surface of the semiconductor substrate 105, performing a patterning process to form a second hole exposing the upper surface of the first portion P1, and partially or completely filling the second hole with an insulating material. The lower source/drain pattern LSD may be separated into a first adjacent lower source/drain pattern LSDa and a second adjacent lower source/drain pattern LSDb by the second portion P2.

Referring to FIG. 20C, the first interlayer insulating layer 110 may be formed to cover or overlap the lower source/drain pattern LSD. The first interlayer insulating layer 110 may cover or overlap the sidewall of the second portion P2. Thereafter, an upper portion of the first interlayer insulating layer 110 may be removed to expose the sidewall of the upper stacked pattern STP2 in the recess RS again. A first liner layer LIN may be formed to conformally cover the first interlayer insulating layer 110. The first liner layer LIN may be an insulating layer formed of one layer or multiple layers.

An upper source/drain pattern USD may be formed on the first liner layer LIN. The second insulating layer ESL2 may be conformally formed on the upper source/drain pattern USD. A second interlayer insulating layer 120 may be formed on the upper source/drain pattern USD. The subsequent process may be the same as FIGS. 15A, 15B, 15C, 16A, 16B, 16C, 17A, 17B, and 17C.

According to some embodiments of the inventive concept, the lower source/drain pattern LSD may be formed to cover the first portion P1. Accordingly, a cross-sectional area of the lower source/drain pattern LSD may be expanded to reduce resistance. As a result, reliability and electrical characteristics of three-dimensional semiconductor devices may be improved.

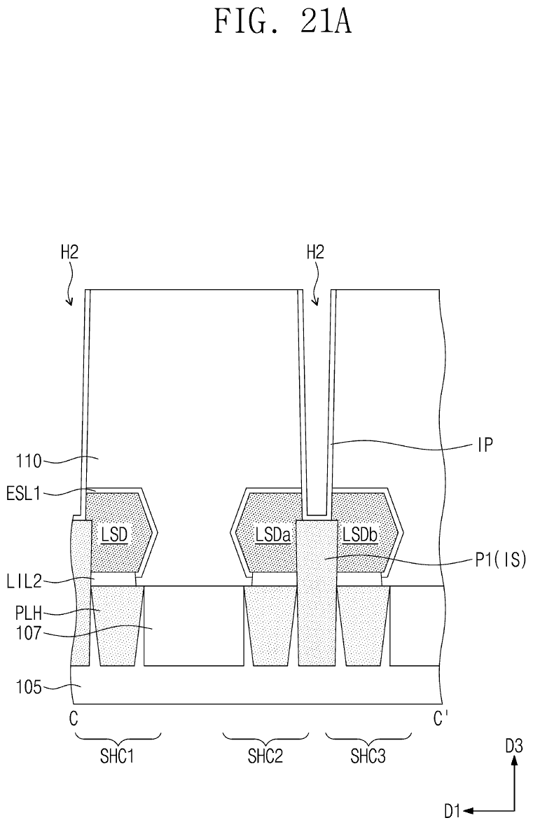

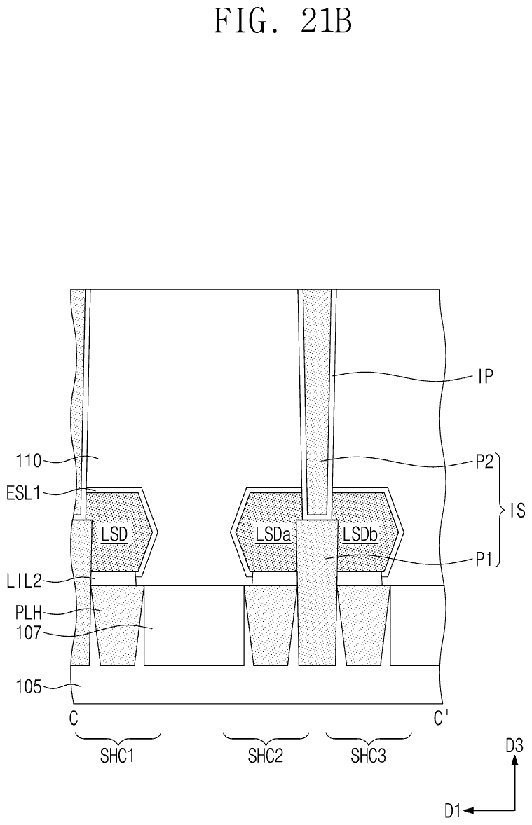

FIGS. 21A and 21B are cross-sectional views for explaining a method of manufacturing a semiconductor device according to some embodiments of the inventive concept. FIGS. 21A and 21B are cross-sectional views for explaining the manufacturing method of the semiconductor device according to FIG. 19B. FIG. 21A may be a process following the manufacturing process corresponding to FIG. 20A.

Referring to FIG. 21A, a first interlayer insulating layer 110 may be formed to cover or overlap the lower source/drain pattern LSD. Second holes H2 exposing the upper surface of the first portion P1 may be formed in the first interlayer insulating layer 110. An insulating pattern IP may be formed in the second holes H2. The insulating pattern IP may cover or overlap the sidewall of the second hole H2 and the exposed upper surface of the first portion P1.

Referring to FIG. 21B, the second portion P2 may be formed by partially or completely filling the second hole H2 with an insulating material. The second portion P2 may be formed on the insulating pattern IP. The second portion P2 may include a material having an etch selectivity different from that of the insulating pattern IP.

Referring again to FIG. 19B, the upper portion of the first interlayer insulating layer 110 may be removed. As the first interlayer insulating layer 110 is removed, the upper portion of the insulating pattern IP may be removed together. The insulating structure IS may not be removed by the above process. The upper surface of the insulating pattern IP that has not been removed may be lower than the upper surface of the lower source/drain pattern LSD. As another example, the upper surface of the insulating pattern IP may be coplanar with the upper surface of the first interlayer insulating layer 110. The sidewall of the upper stacked pattern STP2 may be exposed again in the recess RS. A first liner layer LIN may be formed to conformally cover the first interlayer insulating layer 110.

An upper source/drain pattern USD may be formed on the first liner layer LIN. The second insulating layer ESL2 may be conformally formed on the upper source/drain pattern USD. A second interlayer insulating layer 120 may be formed on the upper source/drain pattern USD. The subsequent process may be the same as FIGS. 15A, 15B, 15C, 16A, 16B, 16C, 17A, 17B, and 17C.

According to some embodiments of the inventive concept, an insulating pattern IP may be interposed between the first portion P1 and the second portion P2. By forming the insulating pattern IP, the width of the second portion P2 may be further reduced. Accordingly, the cross-sectional areas of the upper source/drain pattern USD and lower source/drain pattern LSD may be expanded. Additionally, the interval between adjacent upper active contacts UAC may be narrowed. As a result, the reliability and electrical characteristics of three-dimensional semiconductor devices may be improved.

In the three-dimensional semiconductor device according to the inventive concept, the cutting pattern may be provided on the one side of the logic cell, and the insulating structure may be provided on the other side thereof. The width of the lower portion of the insulating structure may be greater than the width of the upper portion of the insulating structure. For example, the width of the insulating structure may be variously changed discontinuously at the boundary between the upper and lower portions. As the lower and upper portions of the insulating structure are formed sequentially, the electrical shorts that occur during the manufacturing process of the insulating structure may be prevented. Furthermore, the vertical vias may be formed in the cutting pattern, thereby reducing the width of the insulating structure and increasing the integration of the logic cell. As a result, the reliability and the electrical characteristics of three-dimensional semiconductor devices may be improved.

While embodiments are described above, a person skilled in the art may understand that many modifications and variations are made without departing from the spirit and scope of the inventive concept defined in the following claims. Accordingly, the example embodiments of the inventive concept should be considered in all respects as illustrative and not restrictive, with the spirit and scope of the inventive concept being indicated by the appended claims.

What is claimed is:

1. A semiconductor device comprising:
a first active region on a substrate, the first active region including a lower channel pattern and a lower source/drain pattern electrically connected to the lower channel pattern;
a second active region on the first active region, the second active region including an upper channel pattern and an upper source/drain pattern electrically connected to the upper channel pattern;
a gate electrode on the lower channel pattern and the upper channel pattern, wherein the gate electrode extends in a first direction;
an insulating structure on the first active region and the second active region, wherein the insulating structure extends in a second direction that intersects the first direction,
wherein the insulating structure comprises:
a first portion having a first width; and
a second portion on the first portion, the second portion having a second width, and
wherein the first width is greater than the second width.

2. The semiconductor device of claim 1, wherein a wall of the first portion includes a first step surface, and
wherein the first step surface is configured to change the first width to the second width.

3. The semiconductor device of claim 2, wherein a first distance of the first step surface from the substrate is greater than a second distance of an uppermost surface of the lower source/drain pattern from the substrate, and
wherein the first distance is less than a third distance of a lowermost surface of the upper source/drain pattern from the substrate.

4. The semiconductor device of claim 1, wherein the insulating structure further includes a third portion between the first portion and the second portion,
wherein the third portion has a third width, and
wherein the third width is less than a maximum value of the first width and greater than a minimum value of the second width.

5. The semiconductor device of claim 1, further comprising:
an intermediate pattern between the first portion and the second portion,
wherein the intermediate pattern includes a material having an etch selectivity different from that of the insulating structure.

6. The semiconductor device of claim 5, wherein the intermediate pattern extends from a bottom surface of the second portion along a sidewall of the second portion.

7. The semiconductor device of claim 1, wherein the insulating structure extends into the gate electrode, and
wherein a distance of an upper surface of the insulating structure from the substrate is greater than a distance of an upper surface of the gate electrode from the substrate.

8. The semiconductor device of claim 1, wherein a center line of the first portion is spaced apart from a center line of the second portion in the first direction.

9. The semiconductor device of claim 1, wherein the first width and the second width increase as a distance from a lower surface of the insulating structure increases.

10. The semiconductor device of claim 1, further comprising:
a cutting pattern that extends in the second direction on the substrate, wherein the cutting pattern extends from the first active region to the second active region;
a lower active contact electrically connected to the lower source/drain pattern;
an upper active contact electrically connected to the upper source/drain pattern; and
a vertical via electrically connecting the lower active contact and the upper active contact,
wherein the vertical via extends into the cutting pattern.

11. A semiconductor device comprising:
a first active region on a substrate, the first active region including a lower channel pattern and a lower source/drain pattern electrically connected to the lower channel pattern;
a second active region on the first active region, the second active region including an upper channel pattern and an upper source/drain pattern electrically connected to the upper channel pattern;
a gate electrode on the lower channel pattern and the upper channel pattern, wherein the gate electrode extends in a first direction; and
an insulating structure that extends into the first active region and the second active region,
wherein the insulating structure extends in a second direction intersecting the first direction,
wherein the insulating structure comprises:
a first portion in a first active region; and
a second portion on the first portion, and
wherein a first sidewall of the first portion is spaced apart from a second sidewall of the second portion in the first direction.

12. The semiconductor device of claim 11, wherein the first portion includes a first step surface physically connecting the first sidewall and the second sidewall, and
wherein the first step surface is configured to change a width of the first portion to a width of the second portion.

13. The semiconductor device of claim 12, wherein a lowest portion of the first step surface is a greater distance from the substrate than a distance of an upper surface of the lower source/drain pattern from the substrate, and
wherein an uppermost portion of the first step surface is a smaller distance from the substrate than a distance of a lower surface of the upper source/drain pattern from the substrate.

14. The semiconductor device of claim 11, wherein a center line of the first portion is spaced apart from a center line of the second portion in the first direction.

15. The semiconductor device of claim 11, wherein each of a width of the first portion and a width of the second portion increases as a distance from a bottom surface of the substrate increases.

16. A semiconductor device comprising:
a first active region on a substrate, the first active region including a lower channel pattern and a lower source/drain pattern electrically connected to the lower channel pattern;
a second active region on the first active region, the second active region including an upper channel pattern and an upper source/drain pattern electrically connected to the upper channel pattern;
a gate electrode on the lower channel pattern and the upper channel pattern, wherein the gate electrode extends in a first direction;
a lower active contact electrically connected to the lower source/drain pattern;
an upper active contact electrically connected to the upper source/drain pattern;
a cutting pattern on a side of the substrate, wherein the cutting pattern extends in a second direction and the second direction intersects the first direction;
a vertical via that extends into the cutting pattern; and
an insulating structure spaced apart from the cutting pattern in the first direction on the substrate,
wherein the insulating structure includes a first portion in the first active region and a second portion on the second active region, and a width of the first portion is greater than a width of the second portion, and
wherein the vertical via electrically connects the lower active contact and the upper active contact.

17. The semiconductor device of claim 16, wherein a distance of an upper surface of the insulating structure from the substrate is greater than a distance of an upper surface of the gate electrode from the substrate, and
wherein a distance of a lower surface of the insulating structure from the substrate is less than a distance of a lower surface of the gate electrode from the substrate.

18. The semiconductor device of claim 16, wherein a first sidewall of the first portion is spaced apart from a second sidewall of the second portion in the first direction.

19. The semiconductor device of claim 16, wherein the insulating structure is spaced apart from the vertical via in the first direction with the lower source/drain pattern and the upper source/drain pattern therebetween.

20. The semiconductor device of claim 16, further comprising:
an intermediate pattern between the first portion and the second portion,
wherein the intermediate pattern includes a material having an etch selectivity different from at least one of an etch selectivity of the first portion or an etch selectivity of the second portion.
